(19) United States
(12) Patent Application Publication
(10) Pub. No.: US 2023/0291420 A1
(43) Pub. Date: Sep. 14, 2023

(54) INFORMATION INDICATION FOR RAPTOR CODES

(71) Applicant: QUALCOMM INCORPORATED, San Diego, CA (US)

(72) Inventors: Kangqi LIU, San Diego, CA (US); Jian LI, Shanghai (CN); Changlong XU, Beijing (CN); Liangming WU, Beijing (CN); Hao XU, Beijing (CN)

(21) Appl. No.: 18/001,251

(22) PCT Filed: Jun. 11, 2020
(86) PCT No.: PCT/CN2020/095579

§ 371 Date: Dec. 8, 2022

(51) Int. Cl. H03M 13/37; H03M 13/00; H04L 1/00

(52) U.S. Cl. CPC H03M 13/3761; H03M 13/6306; H04L 1/0041

(57) ABSTRACT

Methods, systems, and devices for wireless communications are described. An encoding device (e.g., a base station or user equipment (UE)) may communicate, with a decoding device (e.g., a UE or base station), an indication of a set of encoding symbol identifiers via a control channel. The encoding device may transmit a set of packets associated with a rateless code via a data channel, where each of the set of packets includes an encoding symbol. The decoding device may decode the set of encoding symbols based on the set of encoding symbol identifiers.

### CROSS REFERENCE

The present Application is a 371 national stage filing of International PCT Application No. PCT/CN2020/095579 by LIU et al. entitled “INFORMATION INDICATION FOR RAPTOR CODES,” filed Jun. 11, 2020, which is assigned to the assignee hereof, and which is expressly incorporated by reference in its entirety herein.

### FIELD OF TECHNOLOGY

The following relates generally to wireless communications and more specifically to information indication for raptor codes.

### BACKGROUND

Wireless communications systems are widely deployed to provide various types of communication content such as voice, video, packet data, messaging, broadcast, and so on. These systems may be capable of supporting communication with multiple users by sharing the available system resources (e.g., time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal frequency division multiple access (OFDMA), or discrete Fourier transform spread orthogonal frequency division multiplexing (DFT-S-OFDM). A wireless multiple-access communications system may include one or more base stations or one or more network access nodes, each simultaneously supporting communication for multiple communication devices, which may be otherwise known as user equipment (UE).

In some examples, a transmitting device (e.g., a base station or UE) may transmit a set of packets to a receiving device (e.g., a base station or UE). If the receiving device fails to receive at least one of the packets, the transmitting device may retransmit the set of packets. As the transmitting device performs retransmissions an increased number of times, the latency associated with the receiving device successfully receiving each of the one or more packets increases. As such, methods which reduce the number of times that retransmissions are performed may decrease the latency.

### SUMMARY

The described techniques relate to improved methods, systems, devices, and apparatuses that support information indication for raptor codes. Generally, the described techniques provide for an encoding device (e.g., a base station or user equipment (UE)) to include indications of encoding symbol identifiers, source block numbers, or both in first signaling separate from second signaling conveying one or more associated packets of encoding symbols. For instance, the encoding device may communicate, with a decoding device (e.g., a UE or base station), an indication of a set of encoding symbol identifiers for a set of packets encoded with a rateless code via a control channel. The encoding device may transmit the set of packets via a data channel, where each of the set of packets includes an encoding symbol. The encoding device may also transmit an indication of one or more source block numbers associated with the set of packets. The decoding device may decode the set of encoding symbols based on the set of encoding symbol identifiers or the one or more source block numbers.

A method of wireless communication is described. The method may include communicating an indication of a set of encoding symbol identifiers via a control channel, receiving a set of packets associated with a rateless code via a data channel, where each of the set of packets includes an encoding symbol, and decoding the set of encoding symbols based on the set of encoding symbol identifiers.

An apparatus for wireless communication is described. The apparatus may include a processor, memory coupled with the processor, and instructions stored in the memory. The instructions may be executable by the processor to cause the apparatus to communicate an indication of a set of encoding symbol identifiers via a control channel, receive a set of packets associated with a rateless code via a data channel, where each of the set of packets includes an encoding symbol, and decode the set of encoding symbols based on the set of encoding symbol identifiers.

Another apparatus for wireless communication is described. The apparatus may include means for communicating an indication of a set of encoding symbol identifiers via a control channel, receiving a set of packets associated with a rateless code via a data channel, where each of the set of packets includes an encoding symbol, and decoding the set of encoding symbols based on the set of encoding symbol identifiers.

A non-transitory computer-readable medium storing code for wireless communication is described. The code may include instructions executable by a processor to communicate an indication of a set of encoding symbol identifiers via a control channel, receive a set of packets associated with a rateless code via a data channel, where each of the set of packets includes an encoding symbol, and decode the set of encoding symbols based on the set of encoding symbol identifiers.

In some examples of the method, apparatuses, and non-transitory computer-readable medium described herein, communicating the indication of the set of encoding symbol identifiers may include operations, features, means, or instructions for communicating control signaling via the control channel and including the indication of the set of encoding symbol identifiers.

In some examples of the method, apparatuses, and non-transitory computer-readable medium described herein, the control signaling includes a downlink control information message including the indication of the set of encoding symbol identifiers, a radio resource control message including the indication of the set of encoding symbol identifiers, or a medium access control (MAC) control element message including the indication of the set of encoding symbol identifiers.

In some examples of the method, apparatuses, and non-transitory computer-readable medium described herein, communicating the indication of the set of encoding symbol identifiers may include operations, features, means, or instructions for communicating scheduling information via the control channel, where the set of packets are received on the scheduling information, and the method, apparatuses, and non-transitory computer-readable medium described herein may further include operations, features, means, or instructions generating the set of encoding symbol identifiers based on the scheduling information.

In some examples of the method, apparatuses, and non-transitory computer-readable medium described herein, the scheduling information includes a position of one or more resource blocks, a system frame number, a slot number, or a symbol number, and where generating the set of encoding symbol identifiers may be based on the position of the one or more resource blocks, the system frame number, the slot number, the symbol number, or a combination thereof.

Some examples of the method, apparatuses, and non-transitory computer-readable medium described herein may further include operations, features, means, or instructions for communicating control signaling including an indication of a source block number.

Some examples of the method, apparatuses, and non-transitory computer-readable medium described herein may further include operations, features, means, or instructions for decoding the set of encoding symbols based on communicating the indication of the source block number.

In some examples of the method, apparatuses, and non-transitory computer-readable medium described herein, the control signaling includes a downlink control information message including the indication of the source block number, a radio resource control message including the indication of the source block number, or a medium access control (MAC) control element message including the indication of the source block number.

In some examples of the method, apparatuses, and non-transitory computer-readable medium described herein, each packet of the set of packets excludes any indication of the source block number based on communicating the indication of the source block number.

In some examples of the method, apparatuses, and non-transitory computer-readable medium described herein, communicating the control signaling including the indication of the source block number may include operations, features, means, or instructions for receiving, at a user equipment, the indication of the source block number.

In some examples of the method, apparatuses, and non-transitory computer-readable medium described herein, communicating the control signaling including the indication of the source block number may include operations, features, means, or instructions for transmitting, from a base station, the indication of the source block number.

In some examples of the method, apparatuses, and non-transitory computer-readable medium described herein, receiving the set of packets may include operations, features, means, or instructions for receiving a first transport block, where the first transport block includes a set of first code blocks including the set of packets, and where the set of packets includes a set of first packets associated with a first redundancy version, and the method, apparatuses, and non-transitory computer-readable medium may further include operations, features, means, or instructions for receiving a second transport block, where the second transport block includes a set of second code blocks including a set of second packets associated with a second redundancy version, and transmitting an indication of a number of one or more of the set of second code blocks based on failing to successfully decode the one or more of the set of second code blocks, where the set of first packets may be received based on transmitting the indication of the number.

In some examples of the method, apparatuses, and non-transitory computer-readable medium, each of the set of second code blocks is associated with a respective one of the set of first code blocks, and the method, apparatuses, and non-transitory computer-readable medium described herein may further include operations, features, means, or instructions for identifying a failure to decode a code block of the set of first code blocks that may be unassociated with any of the set of second code blocks, and performing a soft combination procedure using the set of first code blocks and the set of second code blocks based on identifying the failure and the generated set of encoding symbols, where decoding the set of first code blocks may be based on performing the soft combination procedure.

In some examples of the method, apparatuses, and non-transitory computer-readable medium, each of the set of second code blocks is associated with a respective one of the set of first code blocks, and the method, apparatuses, and non-transitory computer-readable medium described herein may further include operations, features, means, or instructions for decoding a code block of the set of first code blocks that may be unassociated with any of the set of second code blocks, where decoding the set of first packets may be based on decoding the code block unassociated with any code blocks of the set of second code blocks.

Some examples of the method, apparatuses, and non-transitory computer-readable medium described herein may further include operations, features, means, or instructions for transmitting an acknowledgement message based on decoding the set of encoding symbols.

In some examples of the method, apparatuses, and non-transitory computer-readable medium described herein, each packet of the set of packets excludes any indication of the set of encoding symbol identifiers based on communicating the indication of the set of encoding symbol identifiers.

In some examples of the method, apparatuses, and non-transitory computer-readable medium described herein, decoding the set of encoding symbols may include operations, features, means, or instructions for performing the decoding according to a raptor code on the set of encoding symbols to generate a set of source symbols.

In some examples of the method, apparatuses, and non-transitory computer-readable medium described herein, communicating the indication of the set of encoding symbol identifiers may include operations, features, means, or instructions for receiving, at a user equipment, the indication of the set of encoding symbol identifiers.

In some examples of the method, apparatuses, and non-transitory computer-readable medium described herein, communicating the indication of the set of encoding symbol identifiers may include operations, features, means, or instructions for transmitting, from a base station, the indication of the set of encoding symbol identifiers.

A method of wireless communication is described. The method may include communicating an indication of a set of encoding symbol identifiers via a control channel and transmitting a set of packets associated with the set of encoding symbol identifiers via a data channel, where each of the set of packets includes an encoding symbol of a rateless code.

An apparatus for wireless communication is described. The apparatus may include a processor, memory coupled with the processor, and instructions stored in the memory. The instructions may be executable by the processor to cause the apparatus to communicate an indication of a set of encoding symbol identifiers via a control channel and transmit a set of packets associated with the set of encoding symbol identifiers via a data channel, where each of the set of packets includes an encoding symbol of a rateless code.

Another apparatus for wireless communication is described. The apparatus may include means for communicating an indication of a set of encoding symbol identifiers via a control channel and transmitting a set of packets associated with the set of encoding symbol identifiers via a data channel, where each of the set of packets includes an encoding symbol of a rateless code.

A non-transitory computer-readable medium storing code for wireless communication is described. The code may include instructions executable by a processor to communicate an indication of a set of encoding symbol identifiers via a control channel and transmit a set of packets associated with the set of encoding symbol identifiers via a data channel, where each of the set of packets includes an encoding symbol of a rateless code.

In some examples of the method, apparatuses, and non-transitory computer-readable medium described herein, communicating the indication of the set of encoding symbol identifiers may include operations, features, means, or instructions for communicating control signaling via the control channel and including the indication of the set of encoding symbol identifiers.

In some examples of the method, apparatuses, and non-transitory computer-readable medium described herein, the control signaling includes a downlink control information message including the indication of the set of encoding symbol identifiers, a radio resource control message including the indication of the set of encoding symbol identifiers, or a medium access control (MAC) control element message including the indication of the set of encoding symbol identifiers.

In some examples of the method, apparatuses, and non-transitory computer-readable medium described herein, communicating the indication of the set of encoding symbol identifiers may include operations, features, means, or instructions for communicating scheduling information via the control channel, and the method, apparatuses, and non-transitory computer-readable medium may further include operations, features, means, or instructions for generating the set of encoding symbol identifiers based on the scheduling information, where communicating the set of packets may be based on the set of encoding symbol identifiers.

In some examples of the method, apparatuses, and non-transitory computer-readable medium described herein, the scheduling information includes a position of one or more resource blocks, a system frame number, a slot number, or a symbol number, and where generating the set of encoding symbol identifiers may be based on the position of the one or more resource blocks, the system frame number, the slot number, the symbol number, or a combination thereof.

Some examples of the method, apparatuses, and non-transitory computer-readable medium described herein may further include operations, features, means, or instructions for communicating control signaling including an indication of a source block number.

In some examples of the method, apparatuses, and non-transitory computer-readable medium described herein, the control signaling includes a downlink control information message including the indication of the source block number, a radio resource control message including the indication of the source block number, or a medium access control (MAC) control element message including the indication of the source block number.

In some examples of the method, apparatuses, and non-transitory computer-readable medium described herein, each packet of the set of packets excludes any indication of the source block number based on receiving the indication of the source block number.

In some examples of the method, apparatuses, and non-transitory computer-readable medium described herein, communicating the control signaling including the indication of the source block number may include operations, features, means, or instructions for receiving, at a user equipment, the indication of the source block number.

In some examples of the method, apparatuses, and non-transitory computer-readable medium described herein, communicating the control signaling including the indication of the source block number may include operations, features, means, or instructions for transmitting, from a base station, the indication of the source block number

In some examples of the method, apparatuses, and non-transitory computer-readable medium described herein, transmitting the set of packets may include operations, features, means, or instructions for transmitting a first transport block, where the first transport block includes a set of first code blocks including the set of packets, and where the set of packets includes a set of first packets associated with a first redundancy version, and the method, apparatuses, and non-transitory computer-readable medium described herein may further include operations, features, means, or instructions for transmitting a second transport block, where the second transport block includes a set of second code blocks including a set of second packets associated with a second redundancy version, and receiving an indication of a number of one or more of the set of second code blocks, where the indication of the number indicates a failure to successfully decode the one or more of the set of second code blocks, where the set of first packets may be transmitted based on receiving the indication of the number.

Some examples of the method, apparatuses, and non-transitory computer-readable medium described herein may further include operations, features, means, or instructions for receiving an acknowledgement message based on transmitting the set of packets.

In some examples of the method, apparatuses, and non-transitory computer-readable medium described herein, each packet of the set of packets excludes any indication of the set of encoding symbol identifiers based on communicating the indication of the set of encoding symbol identifiers.

Some examples of the method, apparatuses, and non-transitory computer-readable medium described herein may further include operations, features, means, or instructions for encoding a set of source symbols using a raptor code to generate the set of encoding symbols.

In some examples of the method, apparatuses, and non-transitory computer-readable medium described herein, communicating the indication of the set of encoding symbol identifiers may include operations, features, means, or instructions for receiving, at a user equipment, the indication of the set of encoding symbol identifiers.

In some examples of the method, apparatuses, and non-transitory computer-readable medium described herein, communicating the indication of the set of encoding symbol identifiers may include operations, features, means, or instructions for transmitting, from a base station, the indication of the set of encoding symbol identifiers.

### BRIEF DESCRIPTION OF THE DRAWINGS

FIG. 1 illustrates an example of a wireless communications system that supports information indication for raptor codes in accordance with aspects of the present disclosure.

FIG. 2 illustrates an example of a wireless communications system that supports information indication for raptor codes in accordance with aspects of the present disclosure.

FIG. 3 illustrates an example of a raptor encoding scheme that supports information indication for raptor codes in accordance with aspects of the present disclosure.

FIG. 4 illustrates an example of a code block decoding scheme that supports information indication for raptor codes in accordance with aspects of the present disclosure.

FIG. 5 illustrates an example of a process flow that supports information indication for raptor codes in accordance with aspects of the present disclosure.

FIGS. 6 and 7 show block diagrams of devices that support information indication for raptor codes in accordance with aspects of the present disclosure.

FIG. 8 shows a block diagram of a communication manager that supports information indication for raptor codes in accordance with aspects of the present disclosure.

FIG. 9 shows a diagram of a system including a user equipment (UE) that supports information indication for raptor codes in accordance with aspects of the present disclosure.

FIG. 10 shows a diagram of a system including a base station that supports information indication for raptor codes in accordance with aspects of the present disclosure.

FIGS. 11 through 14 show flowcharts illustrating methods that support information indication for raptor codes in accordance with aspects of the present disclosure.

### DETAILED DESCRIPTION

A decoding device (e.g., a user equipment (UE) or a base station) may receive a set of packets from an encoding device (e.g., a base station or a UE). The packets may have symbols encoded according to a raptor code, which is an example of a fountain code. Additionally, the packets may include a source block number (SBN) and an encoding symbol identifier (ESI) for each symbol (e.g., in a packet header). However, including the SBN and ESI in the header may lead to increased overhead, which may be undesirable when using raptor codes at the radio link control (RLC) or physical (PHY) layer. In addition, the decoding device may be incapable of performing soft-combining if the header is not received correctly because the symbol information is unknown, where soft-combining refers to a procedure by which the decoding device may combine a code block of a first redundancy version with a second code block of a second redundancy version to aid in decoding.

According to various aspects described herein, the encoding device and the decoding device may communicate indications of the SBN or ESI separately from the set of packets. For example, the encoding device and the decoding device may communicate an indication of the SBN or ESI via control signaling (e.g., downlink control information (DCI) signaling, radio resource control (RRC) signaling, medium access control (MAC) control element (MAC-CE) signaling) and/or via a control channel (e.g., via a physical downlink control channel (PDCCH), a physical uplink control channel (PUCCH)), and the encoding device may transmit the set of packets via a data channel (e.g., via a physical downlink shared channel (PDSCH), a physical uplink shared channel (PUSCH)). Alternatively, the encoding device may communicate scheduling information (e.g., a position of resource blocks (RB), a system frame number (SFN), a slot number, a symbol number) with the decoding device that the encoding device or decoding device may use to generate the ESI. For instance, the encoding device or decoding device may receive the scheduling information and may generate ESIs based on a function of the scheduling information. For uplink communications, the decoding device may provide the indications of the SBN and the ESI. For downlink communications, the encoding device may provide the indications of the SBN and the ESI. For sidelink communications, either the encoding device or the decoding device may provide the indications.

Aspects of the disclosure are initially described in the context of wireless communications systems. Additional aspects of the disclosure are described in the context of a raptor encoding scheme, a code block decoding scheme, and a process flow. Aspects of the disclosure are further illustrated by and described with reference to apparatus diagrams, system diagrams, and flowcharts that relate to information indication for raptor codes.

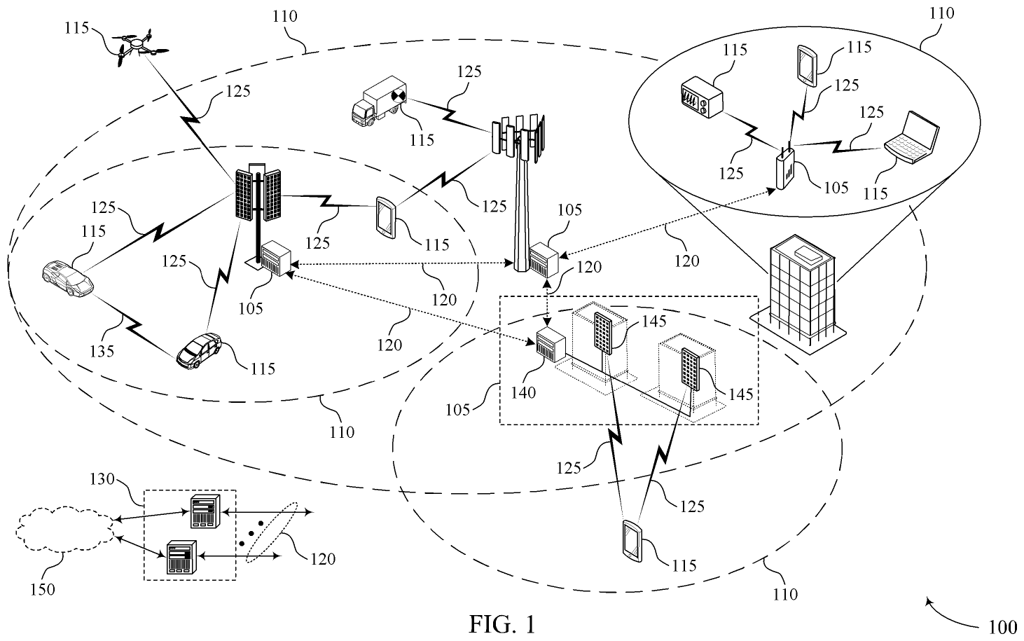

FIG. 1 illustrates an example of a wireless communications system 100 that supports information indication for raptor codes in accordance with aspects of the present disclosure. The wireless communications system 100 may include one or more base stations 105, one or more UEs 115, and a core network 130. In some examples, the wireless communications system 100 may be a Long Term Evolution (LTE) network, an LTE-Advanced (LTE-A) network, an LTE-A Pro network, or a New Radio (NR) network. In some examples, the wireless communications system 100 may support enhanced broadband communications, ultra-reliable (e.g., mission critical) communications, low latency communications, communications with low-cost and low-complexity devices, or any combination thereof.

The base stations 105 may be dispersed throughout a geographic area to form the wireless communications system 100 and may be devices in different forms or having different capabilities. The base stations 105 and the UEs 115 may wirelessly communicate via one or more communication links 125. Each base station 105 may provide a coverage area 110 over which the UEs 115 and the base station 105 may establish one or more communication links 125. The coverage area 110 may be an example of a geographic area over which a base station 105 and a UE 115 may support the communication of signals according to one or more radio access technologies.

The UEs 115 may be dispersed throughout a coverage area 110 of the wireless communications system 100, and each UE 115 may be stationary, or mobile, or both at different times. The UEs 115 may be devices in different forms or having different capabilities. Some example UEs 115 are illustrated in FIG. 1. The UEs 115 described herein may be able to communicate with various types of devices, such as other UEs 115, the base stations 105, or network equipment (e.g., core network nodes, relay devices, integrated access and backhaul (IAB) nodes, or other network equipment), as shown in FIG. 1.

The base stations 105 may communicate with the core network 130, or with one another, or both. For example, the base stations 105 may interface with the core network 130 through one or more backhaul links 120 (e.g., via an S1, N2, N3, or other interface). The base stations 105 may communicate with one another over the backhaul links 120 (e.g., via an X2, Xn, or other interface) either directly (e.g., directly between base stations 105), or indirectly (e.g., via core network 130), or both. In some examples, the backhaul links 120 may be or include one or more wireless links.

One or more of the base stations 105 described herein may include or may be referred to by a person having ordinary skill in the art as a base transceiver station, a radio base station, an access point, a radio transceiver, a NodeB, an eNodeB (eNB), a next-generation NodeB or a giga-NodeB (either of which may be referred to as a gNB), a Home NodeB, a Home eNodeB, or other suitable terminology.

A UE 115 may include or may be referred to as a mobile device, a wireless device, a remote device, a handheld device, or a subscriber device, or some other suitable terminology, where the “device” may also be referred to as a unit, a station, a terminal, or a client, among other examples. A UE 115 may also include or may be referred to as a personal electronic device such as a cellular phone, a personal digital assistant (PDA), a tablet computer, a laptop computer, or a personal computer. In some examples, a UE 115 may include or be referred to as a wireless local loop (WLL) station, an Internet of Things (IoT) device, an Internet of Everything (IoE) device, or a machine type communications (MTC) device, among other examples, which may be implemented in various objects such as appliances, or vehicles, meters, among other examples.

The UEs 115 described herein may be able to communicate with various types of devices, such as other UEs 115 that may sometimes act as relays as well as the base stations 105 and the network equipment including macro eNBs or gNBs, small cell eNBs or gNBs, or relay base stations, among other examples, as shown in FIG. 1.

The UEs 115 and the base stations 105 may wirelessly communicate with one another via one or more communication links 125 over one or more carriers. The term “carrier” may refer to a set of radio frequency spectrum resources having a defined physical layer structure for supporting the communication links 125. For example, a carrier used for a communication link 125 may include a portion of a radio frequency spectrum band (e.g., a bandwidth part (BWP)) that is operated according to one or more physical layer channels for a given radio access technology (e.g., LTE, LTE-A, LTE-A Pro, NR). Each physical layer channel may carry acquisition signaling (e.g., synchronization signals, system information), control signaling that coordinates operation for the carrier, user data, or other signaling. The wireless communications system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers.

Signal waveforms transmitted over a carrier may be made up of multiple subcarriers (e.g., using multi-carrier modulation (MCM) techniques such as orthogonal frequency division multiplexing (OFDM) or discrete Fourier transform spread OFDM (DFT-S-OFDM)). In a system employing MCM techniques, a resource element may consist of one symbol period (e.g., a duration of one modulation symbol) and one subcarrier, where the symbol period and subcarrier spacing are inversely related. The number of bits carried by each resource element may depend on the modulation scheme (e.g., the order of the modulation scheme, the coding rate of the modulation scheme, or both). Thus, the more resource elements that a UE 115 receives and the higher the order of the modulation scheme, the higher the data rate may be for the UE 115. A wireless communications resource may refer to a combination of a radio frequency spectrum resource, a time resource, and a spatial resource (e.g., spatial layers or beams), and the use of multiple spatial layers may further increase the data rate or data integrity for communications with a UE 115.

The time intervals for the base stations 105 or the UEs 115 may be expressed in multiples of a basic time unit which may, for example, refer to a sampling period of Tₛ=1/(Δfₘₐₓ·N_{f}) seconds, where Δfₘₐₓ may represent the maximum supported subcarrier spacing, and N_{f} may represent the maximum supported discrete Fourier transform (DFT) size. Time intervals of a communications resource may be organized according to radio frames each having a specified duration (e.g., 10 milliseconds (ms)). Each radio frame may be identified by an SFN (e.g., ranging from 0 to 1023).

Each frame may include multiple consecutively numbered subframes or slots, and each subframe or slot may have the same duration. In some examples, a frame may be divided (e.g., in the time domain) into subframes, and each subframe may be further divided into a number of slots. Alternatively, each frame may include a variable number of slots, and the number of slots may depend on subcarrier spacing. Each slot may include a number of symbol periods (e.g., depending on the length of the cyclic prefix prepended to each symbol period). In some wireless communications systems 100, a slot may further be divided into multiple mini-slots containing one or more symbols. Excluding the cyclic prefix, each symbol period may contain one or more (e.g., N_{f}) sampling periods. The duration of a symbol period may depend on the subcarrier spacing or frequency band of operation.

A subframe, a slot, a mini-slot, or a symbol may be the smallest scheduling unit (e.g., in the time domain) of the wireless communications system 100 and may be referred to as a transmission time interval (TTI). In some examples, the TTI duration (e.g., the number of symbol periods in a TTI) may be variable. Additionally or alternatively, the smallest scheduling unit of the wireless communications system 100 may be dynamically selected (e.g., in bursts of shortened TTIs (sTTIs)).

Physical channels may be multiplexed on a carrier according to various techniques. A physical control channel and a physical data channel may be multiplexed on a downlink carrier, for example, using one or more of time division multiplexing (TDM) techniques, frequency division multiplexing (FDM) techniques, or hybrid TDM-FDM techniques. A control region (e.g., a control resource set (CORESET)) for a physical control channel may be defined by a number of symbol periods and may extend across the system bandwidth or a subset of the system bandwidth of the carrier. One or more control regions (e.g., CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to a number of control channel resources (e.g., control channel elements (CCEs)) associated with encoded information for a control information format having a given payload size. Search space sets may include common search space sets configured for sending control information to multiple UEs 115 and UE-specific search space sets for sending control information to a specific UE 115.

In some examples, a base station 105 may be movable and therefore provide communication coverage for a moving geographic coverage area 110. In some examples, different geographic coverage areas 110 associated with different technologies may overlap, but the different geographic coverage areas 110 may be supported by the same base station 105. In other examples, the overlapping geographic coverage areas 110 associated with different technologies may be supported by different base stations 105. The wireless communications system 100 may include, for example, a heterogeneous network in which different types of the base stations 105 provide coverage for various geographic coverage areas 110 using the same or different radio access technologies.

The wireless communications system 100 may be configured to support ultra-reliable communications or low-latency communications, or various combinations thereof. For example, the wireless communications system 100 may be configured to support ultra-reliable low-latency communications (URLLC) or mission critical communications. The UEs 115 may be designed to support ultra-reliable, low-latency, or critical functions (e.g., mission critical functions). Ultra-reliable communications may include private communication or group communication and may be supported by one or more mission critical services such as mission critical push-to-talk (MCPTT), mission critical video (MCVideo), or mission critical data (MCData). Support for mission critical functions may include prioritization of services, and mission critical services may be used for public safety or general commercial applications. The terms ultra-reliable, low-latency, mission critical, and ultra-reliable low-latency may be used interchangeably herein.

In some examples, a UE 115 may also be able to communicate directly with other UEs 115 over a device-to-device (D2D) communication link 135 (e.g., using a peer-to-peer (P2P) or D2D protocol). One or more UEs 115 utilizing D2D communications may be within the geographic coverage area 110 of a base station 105. Other UEs 115 in such a group may be outside the geographic coverage area 110 of a base station 105 or be otherwise unable to receive transmissions from a base station 105. In some examples, groups of the UEs 115 communicating via D2D communications may utilize a one-to-many (1:M) system in which each UE 115 transmits to every other UE 115 in the group. In some examples, a base station 105 facilitates the scheduling of resources for D2D communications. In other cases, D2D communications are carried out between the UEs 115 without the involvement of a base station 105.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (e.g., a mobility management entity (MME), an access and mobility management function (AMF)) and at least one user plane entity that routes packets or interconnects to external networks (e.g., a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the base stations 105 associated with the core network 130. User IP packets may be transferred through the user plane entity, which may provide IP address allocation as well as other functions. The user plane entity may be connected to the network operators IP services 150. The operators IP services 150 may include access to the Internet, Intranet(s), an IP Multimedia Subsystem (IMS), or a Packet-Switched Streaming Service.

Some of the network devices, such as a base station 105, may include subcomponents such as an access network entity 140, which may be an example of an access node controller (ANC). Each access network entity 140 may communicate with the UEs 115 through one or more other access network transmission entities 145, which may be referred to as radio heads, smart radio heads, or transmission/reception points (TRPs). Each access network transmission entity 145 may include one or more antenna panels. In some configurations, various functions of each access network entity 140 or base station 105 may be distributed across various network devices (e.g., radio heads and ANCs) or consolidated into a single network device (e.g., a base station 105).

The wireless communications system 100 may operate using one or more frequency bands, typically in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. The UHF waves may be blocked or redirected by buildings and environmental features, but the waves may penetrate structures sufficiently for a macro cell to provide service to the UEs 115 located indoors. The transmission of UHF waves may be associated with smaller antennas and shorter ranges (e.g., less than 100 kilometers) compared to transmission using the smaller frequencies and longer waves of the high frequency (HF) or very high frequency (VHF) portion of the spectrum below 300 MHz.

The wireless communications system 100 may utilize both licensed and unlicensed radio frequency spectrum bands. For example, the wireless communications system 100 may employ License Assisted Access (LAA), LTE-Unlicensed (LTE-U) radio access technology, or NR technology in an unlicensed band such as the 5 GHz industrial, scientific, and medical (ISM) band. When operating in unlicensed radio frequency spectrum bands, devices such as the base stations 105 and the UEs 115 may employ carrier sensing for collision detection and avoidance. In some examples, operations in unlicensed bands may be based on a carrier aggregation configuration in conjunction with component carriers operating in a licensed band (e.g., LAA). Operations in unlicensed spectrum may include downlink transmissions, uplink transmissions, P2P transmissions, or D2D transmissions, among other examples.

A base station 105 or a UE 115 may be equipped with multiple antennas, which may be used to employ techniques such as transmit diversity, receive diversity, multiple-input multiple-output (MIMO) communications, or beamforming. The antennas of a base station 105 or a UE 115 may be located within one or more antenna arrays or antenna panels, which may support MIMO operations or transmit or receive beamforming. For example, one or more base station antennas or antenna arrays may be co-located at an antenna assembly, such as an antenna tower. In some examples, antennas or antenna arrays associated with a base station 105 may be located in diverse geographic locations. A base station 105 may have an antenna array with a number of rows and columns of antenna ports that the base station 105 may use to support beamforming of communications with a UE 115. Likewise, a UE 115 may have one or more antenna arrays that may support various MIMO or beamforming operations. Additionally or alternatively, an antenna panel may support radio frequency beamforming for a signal transmitted via an antenna port.

Beamforming, which may also be referred to as spatial filtering, directional transmission, or directional reception, is a signal processing technique that may be used at a transmitting device or a receiving device (e.g., a base station 105, a UE 115) to shape or steer an antenna beam (e.g., a transmit beam, a receive beam) along a spatial path between the transmitting device and the receiving device. Beamforming may be achieved by combining the signals communicated via antenna elements of an antenna array such that some signals propagating at particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (e.g., with respect to the antenna array of the transmitting device or receiving device, or with respect to some other orientation).

The wireless communications system 100 may be a packet-based network that operates according to a layered protocol stack. In the user plane, communications at the bearer or Packet Data Convergence Protocol (PDCP) layer may be IP-based. An RLC layer may perform packet segmentation and reassembly to communicate over logical channels. A Medium Access Control (MAC) layer may perform priority handling and multiplexing of logical channels into transport channels. The MAC layer may also use error detection techniques, error correction techniques, or both to support retransmissions at the MAC layer to improve link efficiency. In the control plane, the Radio Resource Control (RRC) protocol layer may provide establishment, configuration, and maintenance of an RRC connection between a UE 115 and a base station 105 or a core network 130 supporting radio bearers for user plane data. At the physical layer, transport channels may be mapped to physical channels.

The UEs 115 and the base stations 105 may support retransmissions of data to increase the likelihood that data is received successfully. Hybrid automatic repeat request (HARQ) feedback is one technique for increasing the likelihood that data is received correctly over a communication link 125. HARQ may include a combination of error detection (e.g., using a cyclic redundancy check (CRC)), forward error correction (FEC), and retransmission (e.g., automatic repeat request (ARQ)). HARQ may improve throughput at the MAC layer in poor radio conditions (e.g., low signal-to-noise conditions). In some examples, a device may support same-slot HARQ feedback, where the device may provide HARQ feedback in a specific slot for data received in a previous symbol in the slot. In other cases, the device may provide HARQ feedback in a subsequent slot, or according to some other time interval.

Wireless communications systems are widely deployed to provide various types of communication content such as voice, video, packet data, messaging, broadcast, and so on. These systems may be multiple-access systems capable of supporting communication with multiple users by sharing the available system resources (e.g., time, frequency, and power). A wireless network, for example a wireless local area network (WLAN), such as a Wi-Fi (i.e., Institute of Electrical and Electronics Engineers (IEEE) 802.11) network may include an access point (AP) that may communicate with one or more wireless or mobile devices. The AP may be coupled to a network, such as the Internet, and may enable a mobile device to communicate via the network (or communicate with other devices coupled to the access point). A wireless device may communicate with a network device bi-directionally. For example, in a WLAN, a device may communicate with an associated AP via downlink (e.g., the communication link from the AP to the device) and uplink (e.g., the communication link from the device to the AP). A wireless personal area network (PAN), which may include a Bluetooth connection, may provide for short range wireless connections between two or more paired wireless devices. For example, wireless devices such as cellular phones may utilize wireless PAN communications to exchange information such as audio signals with wireless headsets.

In some cases, an encoding device (e.g., a UE 115 or base station 105) may perform fountain encoding. Fountain codes, which may also be referred to as network codes based on being applied in a network layer, may be rateless codes whose generator matrix may have unlimited columns. Performing fountain coding may involve the encoding device dividing a RLC service data unit (SDU) into K data blocks s₁, . . , s_{K}, where each of the data blocks may contain a same number of bits. The encoding device may then encode the K data blocks into Z packets p₁, . . . , p_{z} using a mother generator matrix. For instance, the encoding device may determine each of the Z packets as p_{z}=Σₖ₌₁^{K}sₖH_{kz}, where H_{kz} may represent a value of an entry at a kth row and an zth column of the mother generator matrix H. Each of the Z packets may correspond to a different column of the mother generator matrix.

When a decoding device receives the fountain encoded transmission from the encoding device, the decoding device may receive at least some of the Z packets (e.g., Q, where Q≤Z). Assuming that the number of Q packets successfully received is greater than a threshold amount (e.g., greater than K), the decoding device may construct an invertible generator matrix G from the Q packets. For instance, the decoding device may identify a header for a first of the packets and may identify, from the header, a column of the mother generator matrix H. The decoding device may perform this identification and may construct the invertible generator matrix by mapping each of the identified columns of the mother generator matrix H to a column of the invertible generator matrix G.

Once the decoding device generates the invertible generator matrix G, the decoding device may reconstruct the K data blocks based on the invertible generator matrix G. For instance, if each of the K recovered data blocks are denoted by cₖ, where 0<k≤K, and each of the packets is denoted by p_{q}, where 0<q≤Q, then cₖ may be equal to Σ_{q=1}^{Q}p_{q}G_{qk}⁻¹, where G_{qk}⁻¹ may represent a qth row and a kth column of the inverted generator matrix G⁻¹. Generally, the data blocks may be recovered if generator matrix G according to the Q data blocks is invertible or if the rank of invertible generator matrix G is K. For conventional ARQ, the original generator matrix may start with a unit matrix.

One type of fountain coding is Luby transform (LT) coding. Performing LT encoding may involve randomly choosing a degree dᵢ from a degree distribution and randomly choosing dᵢ distinct source symbols, which may be a type of data block, with uniform distribution and combining them (e.g., performing one or more exclusive/or (XOR) operations). LT decoding (e.g., belief-propagation (BP) decoding) may involve first finding an encoding symbol tⱼ connected to one source symbol sᵢ (e.g., an encoding symbol whose degree is one). Then the decoding device may set sᵢ to equal tⱼ; may XOR sᵢ to each encoding symbols connected to sᵢ; and may remove each edge connected to source symbol sᵢ. Such a procedure may continue until sᵢ is determined for each value of i. If there is no encoding symbol connected to only one source symbol sᵢ_{ₒ}, the decoding process may fail for that iₒ value. Alternatively, a decoding device may perform a gaussian elimination process (GE) to decode the encoding symbols.

Raptor coding may be an enhancement of LT coding. For instance, performing raptor coding may be similar to performing a low-density parity check (LDPC) and LT coding where a number of degrees is below or equal to a threshold amount (e.g., less than or equal to 3). A raptor code may be applied for multimedia broadcast multicast service (MBMS). Additionally or alternatively, network codes, which may include raptor codes, may be used for IAB.

In some examples, a decoding device (e.g., a UE 115 or a base station 105) may receive a set of packets from an encoding device (e.g., a base station 105 or a UE 115). A header for each of the packets may include an SBN and an ESI for each encoding symbol. The SBN may be an integer identifier (e.g., a first 16 bits of a header) for the source block that the encoding symbols within the packet relate to and the ESI may be an integer identifier (e.g., the last 16 bits of the header) for the encoding symbols within the packet. Each packet may also include one or more encoding symbols. Based on the SBN and ESI, an encoding device and/or a decoding device may determine which source symbols are selected to generate the encoding symbol. In some examples, an encoding device may perform triple generation based on the ESI. For instance, the encoding device may determine (d, a, b)=Trip (K, X), where K is a number of source symbols and X is an ESI value. Generally, d may equal Deg[v], v may be equal to Rand [Y, 0, 2²⁰], Y may be equal to (B+X*A) % Q, and Q may be equal to the largest prime number smaller than 2^{M}, where M may be the size in bits of K or X and % is the modulus operator. In the example where M=16, A may be equal to (53591+J(K)*997) % Q and B may be equal to 10267*(J(K)*997) % Q, where J(K) may be a systematic index associated with K. Additionally, a may equal 1+Rand [Y, 1, L′−1] and b may equal Rand [Y, 2, L′], where L′ may equal the smallest prime greater than or equal to L and where L=K+S+H, where S may correspond to a number of LDPC symbols and H may correspond to a number of half symbols.

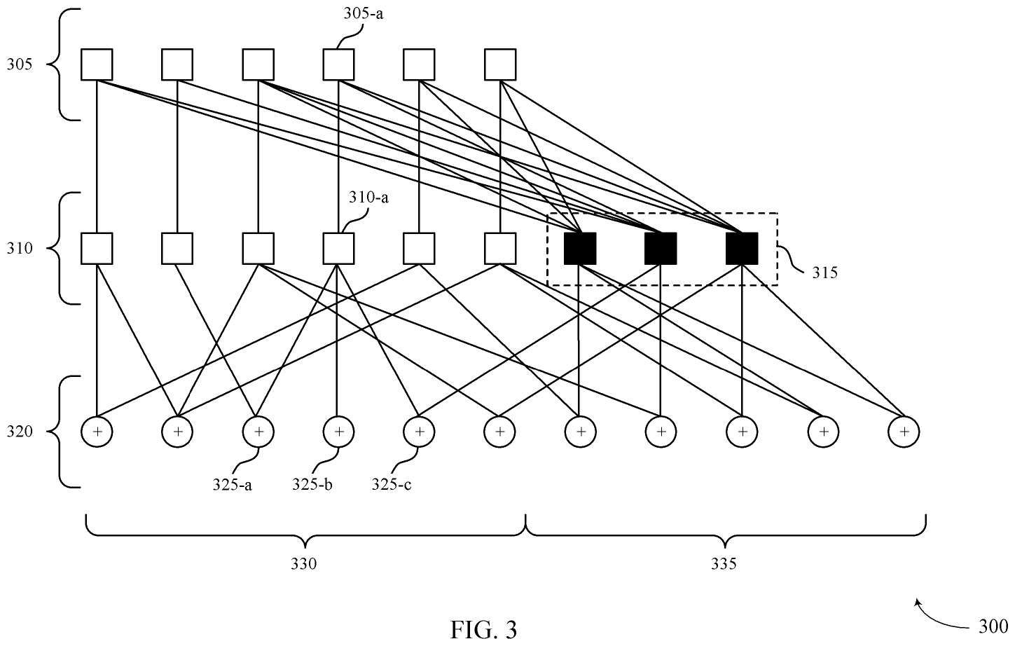

The encoding device may perform LT encoding symbol generation based on the triple generation. For instance, the encoding device may determine P encoding symbols according to LTEnc(K, C[0], C[1], . . . , C[L−1], (d, a, b)). For instance, the decoding device, while b≥L, may determine b=(b+a) % L′ until b<L, where the result may be C [b]. Then for j=1, . . . , min (d−1, L−1), the decoding device may determine b=(b+a) % L. Then, while b≥L, the decoding device may determine b=(b+a) % L′ until b<L. Then the decoding device may determine that result=result^{C[b]}. The result may then be returned. Additional details about encoding symbols may be described with reference to FIG. 3.

In some examples, raptor codes may be used as an erasure-correction code (e.g., in the application layer). In such examples, each encoding symbol may be either decoded correctly or discarded. As such, SBN and ESI may be added as a header file to the encoding symbols. However, when raptor codes are used at the RLC or PHY layer, using SBN and ESI as a header file to the encoding symbols may be disadvantageous. For instance, in cases where the decoding device is unable to decode encoding symbols correctly, the decoding device may not have access to the SBN and ESI information. As such, the decoding device may lose soft information of each of the encoding symbols and may not be capable of determining which source symbols are selected to generate the encoding symbol. In such cases, the decoding device may not be capable of performing soft-combining, where soft-combining refers to a procedure by which the decoding device may combine a code block of a first redundancy version with a second code block of a second redundancy version to aid in decoding.

According to various aspects described herein, the encoding device and the decoding device may communicate the ESI and SBN separately from the encoding symbols. For instance, an encoding device (e.g., a base station 105 or UE 115) may communicate, with a decoding device (e.g., a UE 115 or base station 105), an indication of a set of encoding symbol identifiers associated with a set of packets generated with a rateless code via a control channel. The encoding device may transmit the set of packets via a data channel, where each of the set of packets includes an encoding symbol. The decoding device may decode the set of encoding symbols based on the set of encoding symbol identifiers. Additionally, in some cases, the number of SBN and ESI bits may be reduced (e.g., may be less than 16).

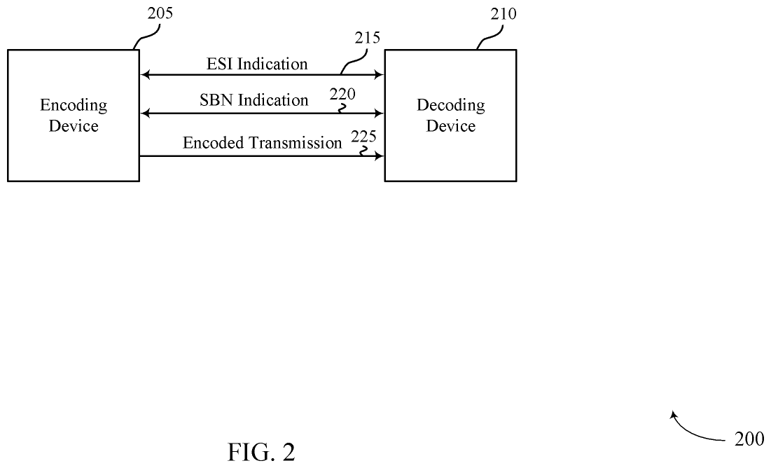

FIG. 2 illustrates an example of a wireless communications system 200 that supports information indication for raptor codes in accordance with aspects of the present disclosure. In some examples, wireless communications system 200 may implement aspects of wireless communications system 100. For instance, encoding device 205 and decoding device 210 may each be examples of a UE 115 or a base station 105 as described with reference to FIG. 1.

At an initial time, an encoding device 205 may have a set of source symbols to indicate to a decoding device 210. Generally, each data of length n bits may be partitioned into K=n/l input symbols (e.g., source symbols 230) such that each input symbol may contain l bits. The encoding device 205 may use these K symbols to generate encoding symbols. To generate each encoding symbol, the encoding device 205 may encode the set of source symbols with a rateless code. For example, if performing raptor coding, the encoding device 205 may select a degree dᵢ from a degree distribution; may select at least one of the source symbols 230 according to the identified degree; and may generate the encoding symbol based on the selected at least one of the source symbols. More details about raptor coding may be described elsewhere herein, for example, with reference to FIG. 3.

Each of the set of encoding symbols may have an associated ESI and SBN. To communicate the ESI, the encoding device 205 may communicate an ESI indication 215 (e.g., an indication of a set of ESIs) with decoding device 210 via a control channel. For instance, one of the encoding device 205 or the decoding device 210 may transmit control signaling including the ESI indication 215 via the control channel to the other of the encoding device 205 or the decoding device 210. The control signaling may include a DCI message including the ESI indication 215, an RRC message including the ESI indication 215, or a MAC-CE message including the ESI indication 215. Alternatively, one of the encoding device 205 or the decoding device 210 may transmit scheduling information via the control channel which the other of the encoding device 205 or the decoding device 210 may use to generate the set of ESIs. The scheduling information may include a position of one or more RBs, an SFN, a slot number, or a symbol number, which the other of the encoding device 205 or the decoding device 210 may use to generate the set of ESIs. For example, the decoding device 210 may determine, for each encoding symbol, ESI=f(scheduling information).

Whether the encoding device 205 or the decoding device 210 provides the ESI indication 215 may be based on a type of communications to be performed between the encoding device 205 and the decoding device 210. For instance, for uplink communications, the decoding device 210 may transmit the ESI indication 215 to the encoding device 205. For downlink communications, the encoding device 205 may transmit the ESI indication 215 to the decoding device 210. For sidelink communications, the encoding device 205 or the decoding device 210 may transmit the ESI indication 215.

To communicate the SBN, the encoding device 205 may communicate an SBN indication 220 (e.g., an indication of the SNB) with decoding device 210 via a control channel. For instance, one of the encoding device 205 or the decoding device 210 may transmit control signaling via the control channel and including the SBN indication 220 to the other of the encoding device 205 or the decoding device 210. The control signaling may include a DCI message including the SBN indication 220, an RRC message including the SBN indication 220, or a MAC-CE message including the SBN indication 220.

Whether the encoding device 205 or the decoding device 210 provides the SBN indication 220 may be based on a type of communications to be performed between the encoding device 205 and the decoding device 210. For instance, for uplink communications, the decoding device 210 may transmit the SBN indication 220 to the encoding device 205. For downlink communications, the encoding device 205 may transmit the SBN indication 220 to the decoding device 210. For sidelink communications, the encoding device 205 or the decoding device 210 may transmit the SBN indication 220.

The encoding device 205 may transmit an encoded transmission 225 to decoding device 210 via a data channel. In some examples, prior to transmitting the encoded transmission 225 and in cases where the encoded transmission 225 is for downlink communications, the encoding device 205 may schedule a downlink data channel (e.g., a PDSCH); generate ESI based on scheduling information; and may perform triple generation and LT encoding symbol generation (e.g., as described in FIG. 1) using the ESI to generate a set of encoding symbols. The encoded transmission 225 may include a first transport block (TB) which may be dividable or partitionable into K first code blocks (CB) with channel coding (e.g., where K is a positive integer, such as 6). Each first CB may include a respective set of packets and each set of packets may include one or more of the set of encoding symbols. In examples where the scheduling information provides the ESI indication 215, the scheduling information may point to resources that the decoding device 210 may use to receive the encoded transmission 225 and/or that the encoding device 205 may use to transmit the encoded transmission 225. The encoded transmission 225 may exclude any indication of the set of ESIs, the SBN, or both based on the encoding device 205 communicating the ESI indication 215, the SBN indication 220, or both, respectively, with the decoding device 210. In cases where the decoding device 210 determines ESI from scheduling information, the encoding symbols may be transmitted at least partially out of order, but may be transmitted based on calculated ESI (e.g., based on a result of f (scheduling information)).

The decoding device 210 may receive the encoded transmission 225 and may decode the one or more encoding symbols of each set of packets, which may be referred to as a set of encoding symbols. In some examples, the decoding device 210 may decode the set of encoding symbols based on the set of ESIs, the SBN, or both. For example, the decoding device 210 may perform the decoding according to a raptor code on the set of encoding symbols to generate a set of source symbols. In some examples where the encoded transmission 225 is a downlink transmission, the decoding device 210 may generate ESI based on received scheduling information.

After receiving the encoded transmission 225, decoding device 210 may provide feedback to the encoding device 205. The type of feedback that the decoding device 210 provides may depend on whether the decoding device successfully recovered the set of source symbols. For instance, if the decoding device has successfully recovered each source symbol in the set of source symbols (e.g., the decoding device 210 has successfully decoded each CB in the TB), the decoding device 210 may transmit an acknowledgement message (e.g., an acknowledgement (ACK)) to the encoding device 205. Alternatively, if the decoding device 210 has failed to successfully recover each source symbol in the set of source symbols (e.g., the decoding device 210 has failed to successfully decode at least one first CB in the first TB), the decoding device 210 may transmit a number of first CBs that the decoding device 210 has failed to decode (e.g., negative acknowledgement (NACK) first CBs or NACKed first CBs).

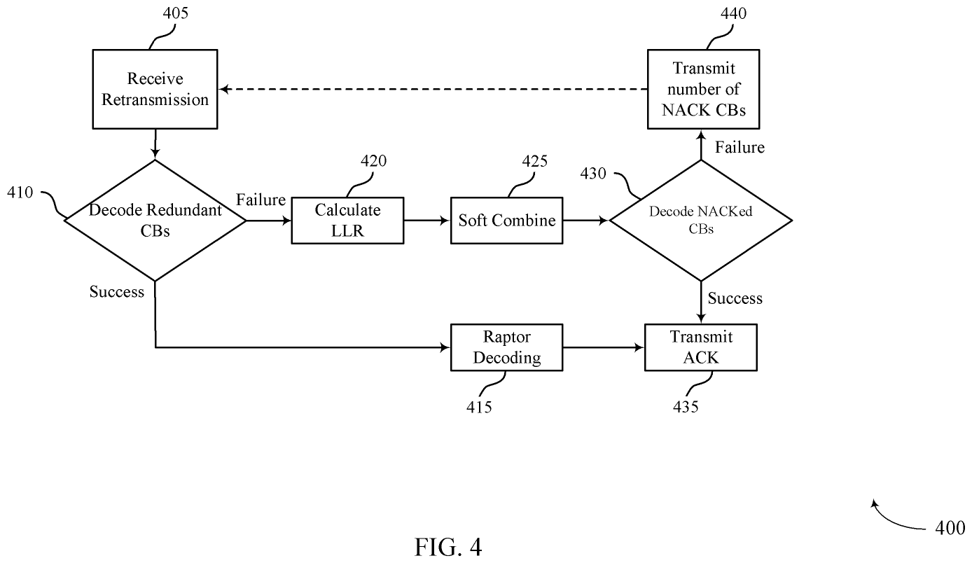

If the decoding device 210 provides a number of NACKed first CBs to the encoding device 205, encoding device 205 may provide a retransmission. The retransmission may include a second TB including L=K+N second CBs, where N refers to a number of redundant second CBs. Redundant second CBs may be second CBs that are constructed using multiple first CBs. The K first CBs of the encoded transmission 225 may be associated with a first redundancy version (RV) and the K non-redundant second CBs of the retransmission may be associated with a second RV. For example, if the K first CBs of the encoded transmission 225 are associated with RV1, the K non-redundant second CBs of the retransmission may be associated with RV2. In a circular buffer, the encoding device 205 may transmit CB_i with RV1, RV2, RV3, and so on. The encoding device 205 may regard the K non-redundant second CBs as source symbols of a systematic raptor code and may generate associated encoding symbols (e.g., the N redundant second CBs) for retransmission. If the decoding device 210 fails to decode the N redundant second CBs, the decoding device 210 may perform a decoding process that utilizes soft-combining, where performing the soft-combining may be based on the ESI. Additional details about this procedure may be described with reference to FIG. 4. It should be noted that SBN, in some cases, may not change in each HARQ process. As such, the SBN indication 220 transmitted for encoded transmission 225 may not be retransmitted for the retransmission.

The techniques as described herein may have one or more advantages. For instance, even if encoding symbols encoded according to a raptor code are not decoded correctly, the decoding device 210 may still be able to determine which source symbols were selected to generate the encoding symbols. Additionally, the decoding device 210 may be able to perform soft-combining, which may provide the decoding device 210 with soft information of NACK-encoding symbols and may, accordingly, aid in the decoding of source symbols.

FIG. 3 illustrates an example of a raptor encoding scheme 300 that supports information indication for raptor codes in accordance with aspects of the present disclosure. In some examples, raptor encoding scheme 300 may be implemented by aspects of wireless communications system 100. For instance, raptor encoding scheme 300 may be an example of a scheme by which an encoding device 205 may encode source symbols.

Initially, an encoding device 205 may have a set of source symbols 305. As part of a pre-coding process, encoding device 205 may generate intermediate symbols 310. Generating intermediate symbols 310 may involve mapping each source symbol 305 to a unique intermediate symbol 310. For instance, source symbol 305-a may map to intermediate symbol 310-a. Additionally, generating intermediate symbols may involve mapping multiple source symbols 305 to each of a set of redundant intermediate symbols 315, which may also be referred to as redundant nodes. The redundant intermediate symbols 315 may include S low-density parity check (LDPC) symbols (e.g., where each source symbol 305 may appear three times over the S LDPC symbols). Additionally or alternatively, the redundant intermediate symbols 315 may include H half symbols (e.g., where each encoding symbol 320 may include ceiling(H/2) source symbols 305). The redundant intermediate symbols 315 may be based on the other intermediate symbols 310 (e.g., the first M intermediate symbols 310). It should be noted that the source symbols as described in FIG. 2 may correspond to source symbols 305 or intermediate symbols 310.

As part of an LT coding process, the encoding device 205 may generate encoding symbols 320. Generating the encoding symbols may involve choosing a degree dᵢ from a degree distribution; choosing or selecting dᵢ distinct intermediate symbols 310 according to a uniform distribution; and combining them (e.g., performing one or more XORs). Using a uniform distribution may ensure that each intermediate symbol 310 is selected approximately a same amount. In one example, encoding device 205 may identify a degree of two; may select intermediate symbol 310-a and another intermediate symbol 310; and may combine (e.g., XOR) them to generate encoding symbol 320-a. In another example, encoding device 205 may identify a degree of one; may select intermediate symbol 310-a and may use intermediate symbol 310-a as encoding symbol 320-b. In yet another example, encoding device 205 may identify a degree of three; may select intermediate symbol 310-a and two other intermediate symbols 310; and may combine (e.g., XOR) them to generate encoding symbol 320-c. Some of the encoding symbols 320 may be referred to as systematic symbols 330 and other of the encoding symbols 320 may be referred to as repair symbols 335.

Performing the procedure described herein may reduce the encoding and decoding complexities of LT codes by reducing the average degree. In such cases, an encoding device 205 may perform raptor coding as described herein, which may use LDPC and an LT code (e.g., a weak LT code) with an average degree that is below or at a threshold amount (e.g., 3).

FIG. 4 illustrates an example of a code block decoding scheme 400 that supports information indication for raptor codes in accordance with aspects of the present disclosure. In some examples, code block decoding scheme 400 may be implemented by aspects of wireless communications system 100. For instance, code block decoding scheme 400 may be an example of a procedure by which a decoding device 210 may decode code blocks of a transmission or retransmission.

As described herein, a decoding device 210 may receive an encoded transmission (e.g., an encoded transmission 225), where the encoded transmission includes a first TB partitionable into a set of first CBs (e.g., 6 first CBs: CB1, CB2, CB3, CB4, CB5, and CB6 with an RV of RV0). The decoding device 210 may perform raptor decoding on the set of first CBs and may successfully decode a first subset (e.g., CB1, CB3, CB4, and CB5) and may fail to decode a second subset (e.g., CB2 and CB6). As such, the decoding device 210 may provide HARQ feedback to the encoding device 205. For instance, the decoding device 210 may indicate a number of first CBs in the second subset (e.g., 2).

Accordingly, encoding device 205 may transmit a retransmission that includes a second TB partitionable into a set of second CBs (e.g., 2 second CBs: CB7, and CB8 with an RV of RV1). Some of the second CBs may be associated with multiple second CBs. For instance, CB7 may be generated by XORing CB2 with CB4 and CB8 may be generated by XORing CB3 with CB5 and CB6.

At 405, the decoding device 210 may receive the retransmission. At 410, the decoding device 210 may perform a first level of decoding (e.g., packet CRC or checksum) to attempt to verify the encoded bits of the redundant second CBs (e.g., CB7 and CB8). If the decoding device 210 successfully receives the encoded bits of the redundant second CBs, the decoding device 210, at 415, may perform raptor decoding on the second subset that the decoding device 210 failed to decode previously (e.g., CB2 and CB6 with RV1).

Alternatively, if the decoding device 210 fails to successfully verify that the encoded bits of the redundant second CB were received correctly, the decoding device 210 may, at 420, calculate log-likelihood ratio (LLR) for the second subset that the decoding device 210 failed to decode previously. For instance, the decoding device 210 may determine an LLR for CB2 with RV1 as LLR(CB7)*sign(CB4) and may determine an LLR for CB6 with RV1 as LLR(CB8)*sign(CB3)*sign(CB5). At 425, the decoding device 210 may perform a soft-combining procedure based on the ESI. For instance, the decoding device 210 may combine CB2 of RV1 with CB2 of RV0 and may combine CB6 of RV1 with CB6 of RV0.

At 430, the decoding device 210 may attempt to successfully decode the soft-combined second CBs. If the decoding device 210 succeeds and/or in cases where the raptor decoding at 415 is performed, the decoding device 210, at 435, may transmit an acknowledgement message (e.g., an ACK) to encoding device 205. If the decoding device 210 fails to successfully decode one or more of the soft-combined second CBs, the decoding device 210, at 440, may transmit a number of the soft-combined second CBs that the decoding device 210 failed to decode (e.g., one if at least one of CB2 and CB6 was successfully decoded and two if neither CB2 nor CB6 was successfully decoded).

In some examples, after the encoding device 205 receives the number of second CBs that the decoding device 210 failed to decode, the encoding device 205 may generate a second retransmission that includes a third TB partitionable into a set of third CBs associated with another RV (e.g., RV2). In such examples, the decoding device 210 may repeat the procedure described herein for the second retransmission.

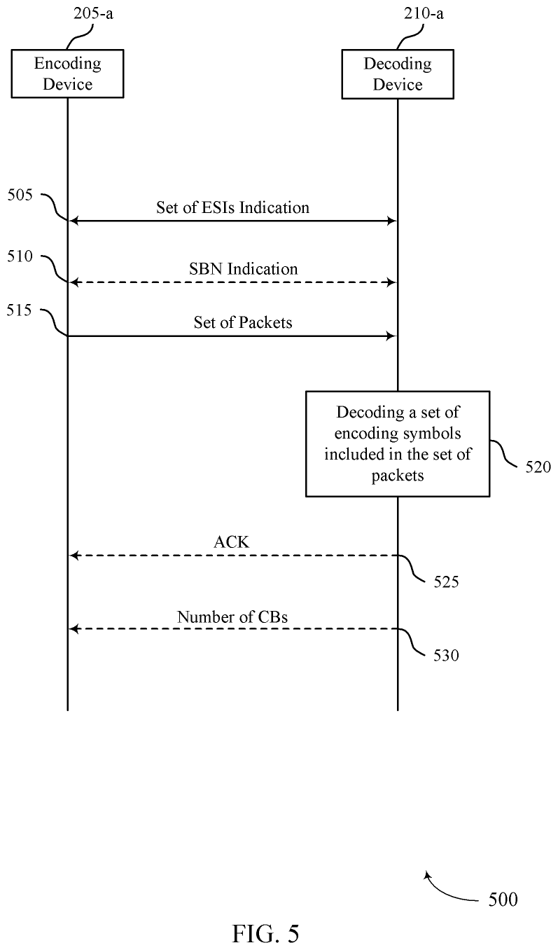

FIG. 5 illustrates an example of a process flow 500 that supports information indication for raptor codes in accordance with aspects of the present disclosure. In some examples, process flow 500 may implement aspects of wireless communications system 100. For instance, process flow 500 may be implemented by an encoding device 205-a, which may be an example of an encoding device 205 as described with reference to FIG. 2, and decoding device 210-a, which may be an example of a decoding device 210 as described with reference to FIG. 2.

At 505, the encoding device 205-a may communicate an indication of a set of encoding symbol identifiers via a control channel with the decoding device 210-a. If encoding device 205-a is a base station and decoding device 210-a is a UE, encoding device 205-a may transmit the indication of the set of encoding symbol identifiers to decoding device 210-a. If encoding device 205-a is a UE and decoding device 210-a is a base station, decoding device 210-a may transmit the indication of the set of encoding symbol identifiers to encoding device 205-a.

In some examples, communicating the indication of the set of encoding symbol identifiers involves communicating control signaling via the control channel and including the set of encoding symbol identifiers. The control signaling may include a DCI message including the indication of the set of encoding symbol identifiers, a RRC message including the indication of the set of encoding symbol identifiers, or a MAC-CE message including the indication of the set of encoding symbol identifiers.

Alternatively, communicating the indication of the set of encoding symbol identifiers may involve communicating scheduling information via the control channel. The encoding device 205-a and/or the decoding device 210-a may generate the set of encoding symbol identifiers based on the scheduling information. The scheduling information may include a position of one or more RBs, an SFN, a slot number, a symbol number, or any combination thereof.

At 510, the encoding device 205-a may communicate control signaling including an indication of a source block number with the decoding device 210-a. If encoding device 205-a is a base station and decoding device 210-a is a UE, encoding device 205-a may transmit the indication of the source block number to decoding device 210-a. If encoding device 205-a is a UE and decoding device 210-a is a base station, decoding device 210-a may transmit the indication of the source block number to encoding device 205-a. The control signaling may include a DCI message including the indication of the source block number, an RRC message including the indication of the source block number, or a MAC-CE message including the indication of the source block number.

At 515, the encoding device 205-a may transmit a set of packets associated with a rateless code (e.g., a raptor code) via a data channel, where each of the set of packets includes an encoding symbol. The decoding device 210-a may receive the set of packets. In some examples, decoding device 210-a may receive and/or encoding device 205-a may transmit the set of packets based on the scheduling information. In some examples, each packet of the set of packets may exclude any indication of the set of encoding symbol identifiers, the source block number, or both based on communicating the indication of the encoding symbol identifiers (e.g., at 505), the source block number (e.g., at 510), or both. In some examples, prior to transmitting the set of packets, the encoding device 205-a may encode a set of source symbols using a raptor code to generate the set of encoding symbols. Transmitting the set of packets may involve transmitting a first TB, where the first TB includes a set of first CBs including the set of packets, and where the set of packets includes a set of first packets associated with a first RV.

At 520, the decoding device 210-a may attempt to decode the set of encoding symbols based on the set of encoding symbol identifiers. In some examples, decoding the set of encoding symbols may be based on communicating the indication of the SFN (e.g., at 510). In some examples, decoding the set of encoding symbols may involve performing the decoding according to a raptor code on the set of encoding symbols to generate a set of source symbols.

At 525, the decoding device 210-a may transmit an acknowledgement message based on decoding the set of encoding symbols. Encoding device 205-a may receive the acknowledgement message.

At 530, the decoding device 210-a may transmit an indication of a number of one or more of the first CBs that the decoding device 210-a failed to successfully decode.

In some examples, the encoding device 205-a may transmit a retransmission to decoding device 210-a. The retransmission may include a second TB, where the second TB includes a set of second CBs including a set of second packets associated with a second RV. Each of the set of first CBs may be associated with a respective one of the set of first CBs. In one example, the decoding device 210-a may identify a failure to decode a CB of the set of first CBs that is unassociated with any of the set of second CBs. In such cases, the decoding device 210-a may perform a soft combination procedure using the set of first CBs and the set of second CBs based on identifying the failure and the generated set of encoding symbols. Additionally, the decoding device 210-a may successfully decode the set of second CBs based on performing the soft combination procedure. In another example, the decoding device 210-a may decode a CB of the set of second CBs that is unassociated with any of the set of first CBs. In such examples, the decoding device 210-a may successfully decode he set of second packets based on decoding the CB unassociated with any CB of the set of first CBs.

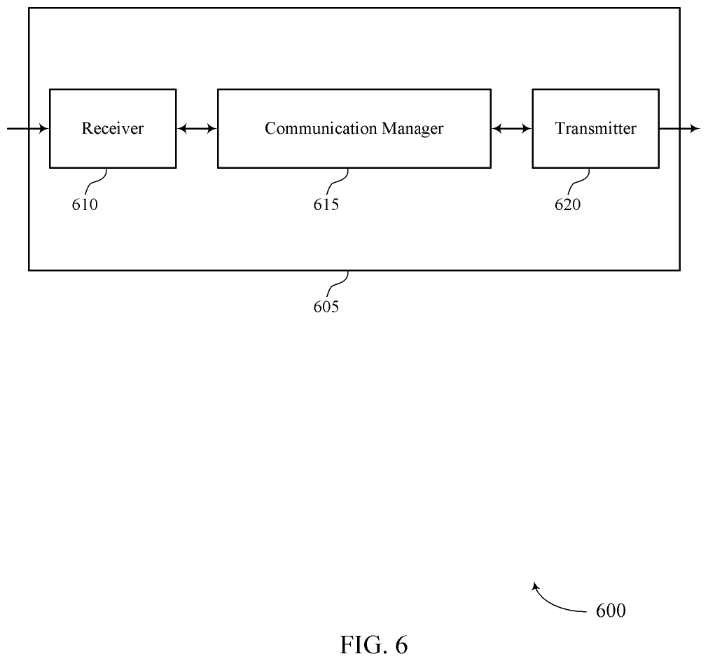

FIG. 6 shows a block diagram 600 of a device 605 that supports information indication for raptor codes in accordance with aspects of the present disclosure. The device 605 may be an example of aspects of a UE 115 or base station 105 as described herein. The device 605 may include a receiver 610, a communication manager 615, and a transmitter 620. The device 605 may also include a processor. Each of these components may be in communication with one another (e.g., via one or more buses).

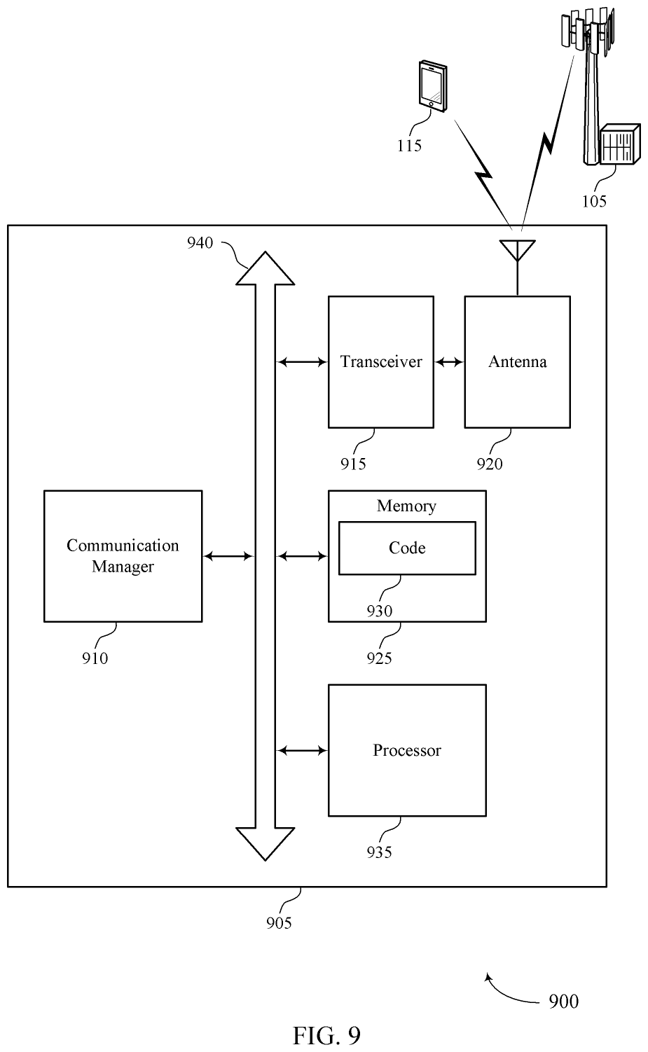

The receiver 610 may receive information such as packets, user data, or control information associated with various information channels (e.g., control channels, data channels, and information related to information indication for raptor codes, etc.). Information may be passed on to other components of the device 605. The receiver 610 may be an example of aspects of the transceiver 915 described with reference to FIG. 9. The receiver 610 may utilize a single antenna or a set of antennas.

The communication manager 615 may communicate an indication of a set of encoding symbol identifiers via a control channel; receive a set of packets associated with a rateless code via a data channel, where each of the set of packets includes an encoding symbol; and decode the set of encoding symbols based on the set of encoding symbol identifiers. The communication manager 615 may also communicate an indication of a set of encoding symbol identifiers via a control channel and transmit a set of packets associated with the set of encoding symbol identifiers via a data channel, where each of the set of packets includes an encoding symbol of a rateless code. The communication manager 615 may be an example of aspects of the communication manager 910 or 1010 as described herein.

The communication manager 615, or its sub-components, may be implemented in hardware, code (e.g., software or firmware) executed by a processor, or any combination thereof. If implemented in code executed by a processor, the functions of the communication manager 615, or its sub-components may be executed by a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described in the present disclosure.

The communication manager 615, or its sub-components, may be physically located at various positions, including being distributed such that portions of functions are implemented at different physical locations by one or more physical components. In some examples, the communication manager 615, or its sub-components, may be a separate and distinct component in accordance with various aspects of the present disclosure. In some examples, the communication manager 615, or its sub-components, may be combined with one or more other hardware components, including but not limited to an input/output (I/O) component, a transceiver, a network server, another computing device, one or more other components described in the present disclosure, or a combination thereof in accordance with various aspects of the present disclosure.

The transmitter 620 may transmit signals generated by other components of the device 605. In some examples, the transmitter 620 may be collocated with a receiver 610 in a transceiver module. For example, the transmitter 620 may be an example of aspects of the transceiver 915 described with reference to FIG. 9. The transmitter 620 may utilize a single antenna or a set of antennas.

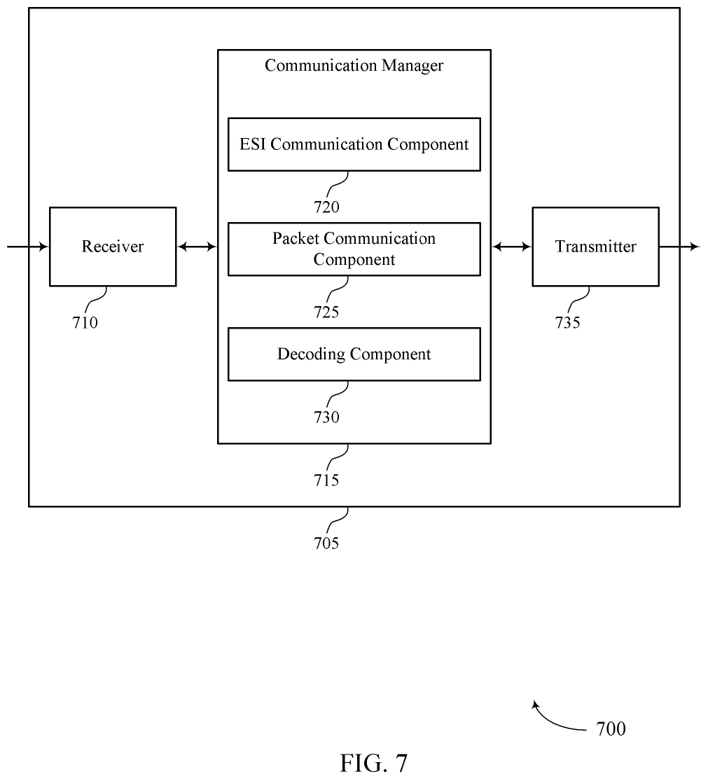

FIG. 7 shows a block diagram 700 of a device 705 that supports information indication for raptor codes in accordance with aspects of the present disclosure. The device 705 may be an example of aspects of a device 605, a UE 115, or a base station 105 as described herein. The device 705 may include a receiver 710, a communication manager 715, and a transmitter 735. The device 705 may also include a processor. Each of these components may be in communication with one another (e.g., via one or more buses).

The receiver 710 may receive information such as packets, user data, or control information associated with various information channels (e.g., control channels, data channels, and information related to information indication for raptor codes, etc.). Information may be passed on to other components of the device 705. The receiver 710 may be an example of aspects of the transceiver 915 described with reference to FIG. 9. The receiver 710 may utilize a single antenna or a set of antennas.

The communication manager 715 may be an example of aspects of the communication manager 615 as described herein. The communication manager 715 may include an ESI communication component 720, a packet communication component 725, and a decoding component 730. The communication manager 715 may be an example of aspects of the communication manager 910 or 1010 as described herein.

The ESI communication component 720 may communicate an indication of a set of encoding symbol identifiers via a control channel.

The packet communication component 725 may receive a set of packets associated with a rateless code via a data channel, where each of the set of packets includes an encoding symbol. The packet communication component 725 may transmit a set of packets associated with the set of encoding symbol identifiers via a data channel, where each of the set of packets includes an encoding symbol of a rateless code.

The decoding component 730 may decode the set of encoding symbols based on the set of encoding symbol identifiers.

The transmitter 735 may transmit signals generated by other components of the device 705. In some examples, the transmitter 735 may be collocated with a receiver 710 in a transceiver module. For example, the transmitter 735 may be an example of aspects of the transceiver 915 described with reference to FIG. 9. The transmitter 735 may utilize a single antenna or a set of antennas.

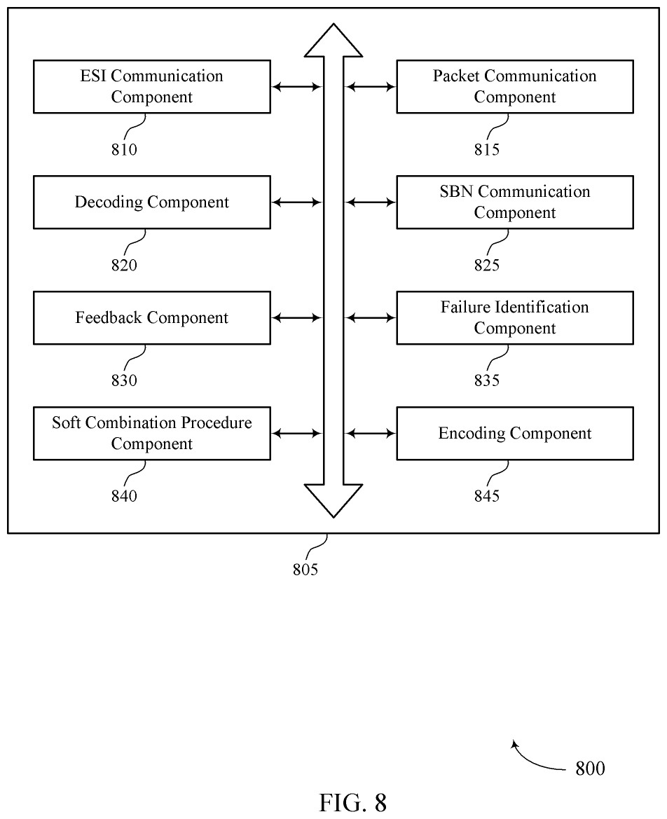

FIG. 8 shows a block diagram 800 of a communication manager 805 that supports information indication for raptor codes in accordance with aspects of the present disclosure. The communication manager 805 may be an example of aspects of a communication manager 615, a communication manager 715, or a communication manager 910 described herein. The communication manager 805 may include an ESI communication component 810, a packet communication component 815, a decoding component 820, a SBN communication component 825, a feedback component 830, a failure identification component 835, a soft combination procedure component 840, and an encoding component 845. Each of these modules may communicate, directly or indirectly, with one another (e.g., via one or more buses).

The ESI communication component 810 may communicate an indication of a set of encoding symbol identifiers via a control channel. In some examples, the ESI communication component 810 communicating (e.g., transmitting or receiving) the indication of the set of encoding symbol identifiers may involve the ESI communication component 810 communicating control signaling via the control channel and including the indication of the set of encoding symbol identifiers. In some cases, the control signaling includes a downlink control information message including the indication of the set of encoding symbol identifiers, a radio resource control message including the indication of the set of encoding symbol identifiers, or a medium access control (MAC) control element message including the indication of the set of encoding symbol identifiers.

In some examples, the ESI communication component 810 communicating the indication of the set of encoding symbol identifiers may involve the ESI communication component 810 communicating (e.g., transmitting or receiving) scheduling information via the control channel. In some such examples, the set of packets may be communicated based on the scheduling information. In some examples, the ESI communication component 810 may generate the set of encoding symbol identifiers based on the scheduling information. In some cases, the scheduling information includes a position of one or more resource blocks, a system frame number, a slot number, or a symbol number, and where generating the set of encoding symbol identifiers is based on the position of the one or more resource blocks, the system frame number, the slot number, the symbol number, or a combination thereof.

In some examples, the ESI communication component 810 communicating the indication of the set of encoding symbol identifiers may involve the ESI communication component 810 receiving, at a user equipment, the indication of the set of encoding symbol identifiers. In some examples, the ESI communication component 810 communicating the indication of the set of encoding symbol identifiers may involve the ESI communication component 810 transmitting, from a base station, the indication of the set of encoding symbol identifiers. In some examples, the ESI communication component 810 may communicate control signaling via the control channel and including the indication of the set of encoding symbol identifiers. In some examples, the ESI communication component 810 may generate the set of encoding symbol identifiers based on the scheduling information, where transmitting the set of packets is based on the set of encoding symbol identifiers.

In some examples, the ESI communication component 810 may receive, at a user equipment, the indication of the set of encoding symbol identifiers. In some examples, the ESI communication component 810 may transmit, from a base station, the indication of the set of encoding symbol identifiers. In some cases, the control signaling includes a downlink control information message including the indication of the set of encoding symbol identifiers, a radio resource control message including the indication of the set of encoding symbol identifiers, or a medium access control (MAC) control element message including the indication of the set of encoding symbol identifiers. In some cases, the scheduling information includes a position of one or more resource blocks, a system frame number, a slot number, or a symbol number, and where generating the set of encoding symbol identifiers is based on the position of the one or more resource blocks, the system frame number, the slot number, the symbol number, or a combination thereof.

The packet communication component 815 may receive a set of packets associated with a rateless code via a data channel, where each of the set of packets includes an encoding symbol. In some examples, each packet of the set of packets may exclude any indication of a source block number based on the SBN communication component 825 communicating control signaling including an indication of the source block number. In some examples, each packet of the set of packets may exclude any indication of the set of encoding symbol identifiers based on the ESI communication component 810 communicating the indication of the set of encoding symbol identifiers. In some examples, transmit a set of packets associated with the set of encoding symbol identifiers via a data channel, where each of the set of packets includes an encoding symbol of a rateless code.

In some examples, the packet communication component 815 receiving the set of packets may involve the packet communication component 815 receiving a first transport block, where the first transport block includes a set of first code blocks including the set of packets, and where the set of packets includes a set of first packets associated with a first redundancy version. In some such examples, the packet communication component 815 may receive a second transport block, where the second transport block includes a set of second code blocks including a set of second packets associated with a second redundancy version. In some examples, each of the set of second code blocks may be associated with a respective one of the set of first code blocks.

In some examples, the packet communication component 815 transmitting the set of packets may involve the packet communication component 815 transmitting a first transport block, where the first transport block includes a set of first code blocks including the set of packets, and where the set of packets includes a set of first packets associated with a first redundancy version. In some such examples, the packet communication component 815 may transmit a second transport block, where the second transport block includes a set of second code blocks including a set of second packets associated with a second redundancy version.

The decoding component 820 may decode the set of encoding symbols based on the set of encoding symbol identifiers. In some examples, decoding the set of encoding symbols may be based on communicating the indication of the source block number. In some examples, the decoding component 820 may decode a code block of the set of first code blocks that is unassociated with any of the set of second code blocks (e.g., a redundant code block), where decoding the set of first packets is based on decoding the code block unassociated with any code block of the set of second code blocks. In some examples, the decoding component 820 decoding the set of encoding symbols involves the decoding component 820 performing the decoding according to a raptor code on the set of encoding symbols to generate a set of source symbols.

The SBN communication component 825 may communicate control signaling including an indication of a source block number. In some cases, the control signaling includes a downlink control information message including the indication of the source block number, a radio resource control message including the indication of the source block number, or a medium access control (MAC) control element message including the indication of the source block number. In some examples, the SBN communication component 825 communicating the control signaling may involve the SBN communication component 825 receiving, at a user equipment, the indication of the source block number. In some examples, the SBN communication component 825 communicating the control signaling may involve the SBN communication component 825 transmitting, from a base station, the indication of the source block number. In some examples, the SBN communication component 825 may communicate control signaling including an indication of a source block number. In some examples, the SBN communication component 825 may receive, at a user equipment, the indication of the source block number. In some examples, the SBN communication component 825 may transmit, from a base station, the indication of the source block number. In some cases, the control signaling includes a downlink control information message including the indication of the source block number, a radio resource control message including the indication of the source block number, or a medium access control (MAC) control element message including the indication of the source block number.

The feedback component 830 may transmit an indication of a number of one or more of the set of code blocks based on failing to successfully decode the one or more of the set of code blocks, where the set of first packets are received (e.g., by the packet communication component 815) based on transmitting the indication of the number. In some examples, the feedback component 830 may transmit an acknowledgement message based on decoding the set of encoding symbols. In some examples, the feedback component 830 may receive an indication of a number of one or more of the set of code blocks, where the indication of the number indicates a failure to successfully decode the one or more of the set of code blocks, where the set of first packets are transmitted (e.g., by the packet communication component 815) based on receiving the indication of the number. In some examples, the feedback component 830 may receive an acknowledgement message based on transmitting the set of packets.

The failure identification component 835 may identify a failure to decode a code block of the set of first code blocks that is unassociated with any of the set of second code blocks.

The soft combination procedure component 840 may perform a soft combination procedure using the set of first code blocks and the set of second code blocks based on identifying the failure and the generated set of encoding symbols, where decoding the set of first code blocks (e.g., by decoding component 820) is based on performing the soft combination procedure.

The encoding component 845 may encode a set of source symbols using a raptor code to generate the set of encoding symbols.

FIG. 9 shows a diagram of a system 900 including a device 905 that supports information indication for raptor codes in accordance with aspects of the present disclosure. The device 905 may be an example of or include the components of device 605, device 705, or a UE 115 as described herein. The device 905 may include components for bi-directional voice and data communications including components for transmitting and receiving communications, including a communication manager 910, a transceiver 915, an antenna 920, memory 925, and a processor 935. These components may be in electronic communication via one or more buses (e.g., bus 940).

The communication manager 910 may communicate an indication of a set of encoding symbol identifiers via a control channel; receive a set of packets associated with a rateless code via a data channel, where each of the set of packets includes an encoding symbol; and decode the set of encoding symbols based on the set of encoding symbol identifiers. The communication manager 910 may also communicate an indication of a set of encoding symbol identifiers via a control channel and transmit a set of packets associated with the set of encoding symbol identifiers via a data channel, where each of the set of packets includes an encoding symbol of a rateless code.

The transceiver 915 may communicate bi-directionally, via one or more antennas, wired, or wireless links as described above. For example, the transceiver 915 may represent a wireless transceiver and may communicate bi-directionally with another wireless transceiver. The transceiver 915 may also include a modem to modulate the packets and provide the modulated packets to the antennas for transmission, and to demodulate packets received from the antennas.

In some cases, the wireless device may include a single antenna 920. However, in some cases the device may have more than one antenna 920, which may be capable of concurrently transmitting or receiving multiple wireless transmissions.

The memory 925 may include random-access memory (RAM) and read-only memory (ROM). The memory 925 may store computer-readable, computer-executable code 930 including instructions that, when executed, cause the processor to perform various functions described herein. In some cases, the memory 925 may contain, among other things, a basic input/output system (BIOS) which may control basic hardware or software operation such as the interaction with peripheral components or devices.

The code 930 may include instructions to implement aspects of the present disclosure, including instructions to support wireless communications. The code 930 may be stored in a non-transitory computer-readable medium such as system memory or other type of memory. In some cases, the code 930 may not be directly executable by the processor 935 but may cause a computer (e.g., when compiled and executed) to perform functions described herein.

The processor 935 may include an intelligent hardware device, (e.g., a general-purpose processor, a DSP, a CPU, a microcontroller, an ASIC, an FPGA, a programmable logic device, a discrete gate or transistor logic component, a discrete hardware component, or any combination thereof). In some cases, the processor 935 may be configured to operate a memory array using a memory controller. In other cases, a memory controller may be integrated into the processor 935. The processor 935 may be configured to execute computer-readable instructions stored in a memory (e.g., the memory 925) to cause the device 905 to perform various functions (e.g., functions or tasks supporting information indication for raptor codes).

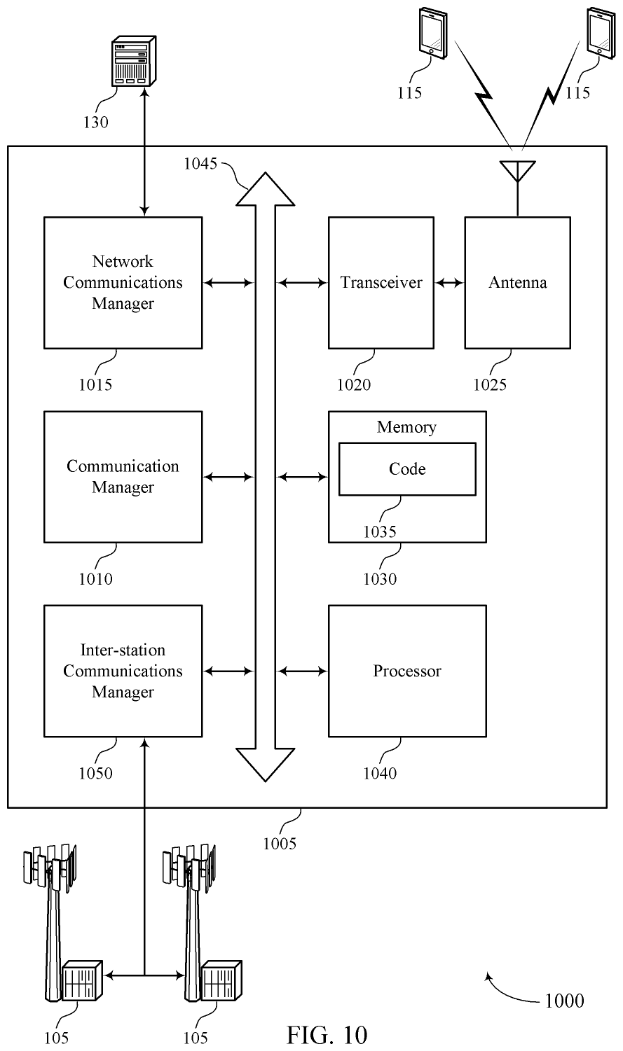

FIG. 10 shows a diagram of a system 1000 including a device 1005 that supports information indication for raptor codes in accordance with aspects of the present disclosure. The device 1005 may be an example of or include the components of device 605, device 705, or a base station 105 as described herein. The device 1005 may include components for bi-directional voice and data communications including components for transmitting and receiving communications, including a communication manager 1010, a transceiver 1015, an antenna 1020, memory 1025, and a processor 1035. These components may be in electronic communication via one or more buses (e.g., bus 1040).

The communication manager 1010 may communicate an indication of a set of encoding symbol identifiers via a control channel; receive a set of packets associated with a rateless code via a data channel, where each of the set of packets includes an encoding symbol; and decode the set of encoding symbols based on the set of encoding symbol identifiers. The communication manager 1010 may also communicate an indication of a set of encoding symbol identifiers via a control channel and transmit a set of packets associated with the set of encoding symbol identifiers via a data channel, where each of the set of packets includes an encoding symbol of a rateless code.

The transceiver 1015 may communicate bi-directionally, via one or more antennas, wired, or wireless links as described above. For example, the transceiver 1015 may represent a wireless transceiver and may communicate bi-directionally with another wireless transceiver. The transceiver 1015 may also include a modem to modulate the packets and provide the modulated packets to the antennas for transmission, and to demodulate packets received from the antennas.

In some cases, the wireless device may include a single antenna 1020. However, in some cases the device may have more than one antenna 1020, which may be capable of concurrently transmitting or receiving multiple wireless transmissions.

The memory 1025 may include RAM and ROM. The memory 1025 may store computer-readable, computer-executable code 1030 including instructions that, when executed, cause the processor to perform various functions described herein. In some cases, the memory 1025 may contain, among other things, a BIOS which may control basic hardware or software operation such as the interaction with peripheral components or devices.

The code 1030 may include instructions to implement aspects of the present disclosure, including instructions to support wireless communications. The code 1030 may be stored in a non-transitory computer-readable medium such as system memory or other type of memory. In some cases, the code 1030 may not be directly executable by the processor 1035 but may cause a computer (e.g., when compiled and executed) to perform functions described herein.

The processor 1035 may include an intelligent hardware device, (e.g., a general-purpose processor, a DSP, a CPU, a microcontroller, an ASIC, an FPGA, a programmable logic device, a discrete gate or transistor logic component, a discrete hardware component, or any combination thereof). In some cases, the processor 1035 may be configured to operate a memory array using a memory controller. In other cases, a memory controller may be integrated into the processor 1035. The processor 1035 may be configured to execute computer-readable instructions stored in a memory (e.g., the memory 1025) to cause the device 1005 to perform various functions (e.g., functions or tasks supporting information indication for raptor codes).

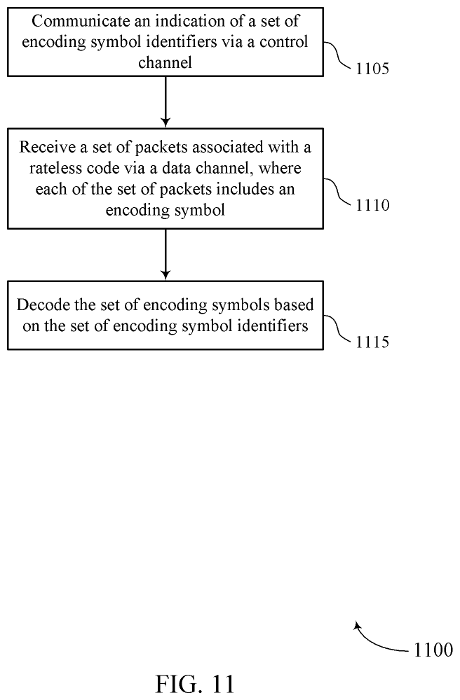

FIG. 11 shows a flowchart illustrating a method 1100 that supports information indication for raptor codes in accordance with aspects of the present disclosure. The operations of method 1100 may be implemented by a UE 115 or base station 105 or its components as described herein. For example, the operations of method 1100 may be performed by a communication manager as described with reference to FIGS. 6 through 10. In some examples, a UE or base station may execute a set of instructions to control the functional elements of the UE or base station to perform the described functions. Additionally or alternatively, a UE or base station may perform aspects of the described functions using special-purpose hardware.

At 1105, the UE or base station may communicate an indication of a set of encoding symbol identifiers via a control channel. The operations of 1105 may be performed according to the methods described herein. In some examples, aspects of the operations of 1105 may be performed by an ESI communication component as described with reference to FIGS. 6 through 10.

At 1110, the UE or base station may receive a set of packets associated with a rateless code via a data channel, where each of the set of packets includes an encoding symbol. The operations of 1110 may be performed according to the methods described herein. In some examples, aspects of the operations of 1110 may be performed by a packet communication component as described with reference to FIGS. 6 through 10.

At 1115, the UE or base station may decode the set of encoding symbols based on the set of encoding symbol identifiers. The operations of 1115 may be performed according to the methods described herein. In some examples, aspects of the operations of 1115 may be performed by a decoding component as described with reference to FIGS. 6 through 10.

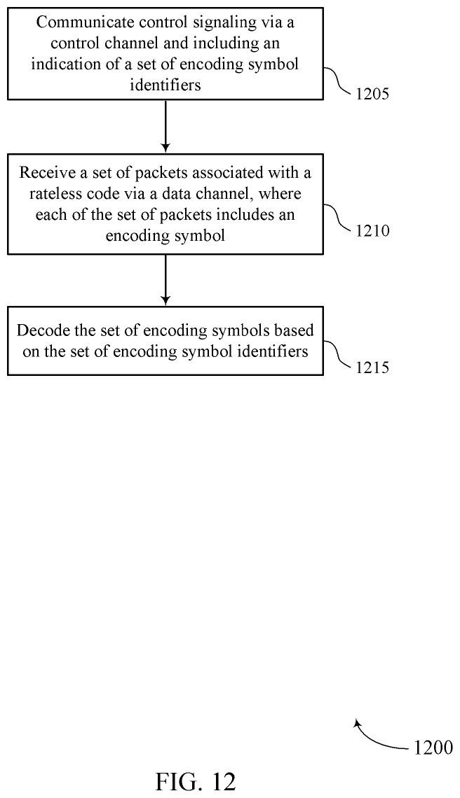

FIG. 12 shows a flowchart illustrating a method 1200 that supports information indication for raptor codes in accordance with aspects of the present disclosure. The operations of method 1200 may be implemented by a UE 115 or base station 105 or its components as described herein. For example, the operations of method 1200 may be performed by a communication manager as described with reference to FIGS. 6 through 10. In some examples, a UE or base station may execute a set of instructions to control the functional elements of the UE or base station to perform the described functions. Additionally or alternatively, a UE or base station may perform aspects of the described functions using special-purpose hardware.

At 1205, the UE or base station may communicate control signaling via a control channel and including an indication of a set of encoding symbol identifiers. The operations of 1205 may be performed according to the methods described herein. In some examples, aspects of the operations of 1205 may be performed by an ESI communication component as described with reference to FIGS. 6 through 10.

At 1210, the UE or base station may receive a set of packets associated with a rateless code via a data channel, where each of the set of packets includes an encoding symbol. The operations of 1210 may be performed according to the methods described herein. In some examples, aspects of the operations of 1210 may be performed by a packet communication component as described with reference to FIGS. 6 through 10.

At 1215, the UE or base station may decode the set of encoding symbols based on the set of encoding symbol identifiers. The operations of 1215 may be performed according to the methods described herein. In some examples, aspects of the operations of 1215 may be performed by a decoding component as described with reference to FIGS. 6 through 10.

At 1220, the UE or base station may communicate control signaling via the control channel and including the indication of the set of encoding symbol identifiers. The operations of 1220 may be performed according to the methods described herein. In some examples, aspects of the operations of 1220 may be performed by an ESI communication component as described with reference to FIGS. 6 through 10.

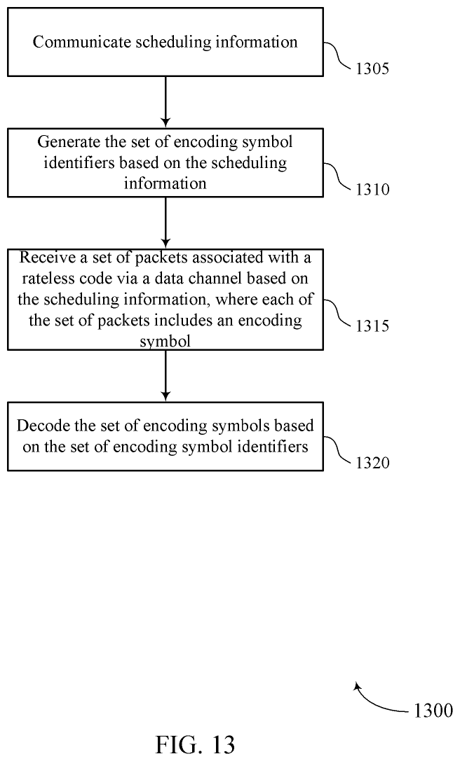

FIG. 13 shows a flowchart illustrating a method 1300 that supports information indication for raptor codes in accordance with aspects of the present disclosure. The operations of method 1300 may be implemented by a UE 115 or base station 105 or its components as described herein. For example, the operations of method 1300 may be performed by a communication manager as described with reference to FIGS. 6 through 10. In some examples, a UE or base station may execute a set of instructions to control the functional elements of the UE or base station to perform the described functions. Additionally or alternatively, a UE or base station may perform aspects of the described functions using special-purpose hardware.

At 1305, the UE or base station may communicate scheduling information. The operations of 1305 may be performed according to the methods described herein. In some examples, aspects of the operations of 1305 may be performed by an ESI communication component as described with reference to FIGS. 6 through 10.

At 1310, the UE or base station may generate the set of encoding symbol identifiers based on the scheduling information. The operations of 1310 may be performed according to the methods described herein. In some examples, aspects of the operations of 1310 may be performed by an ESI communication component as described with reference to FIGS. 6 through 10.

At 1315, the UE or base station may receive a set of packets associated with a rateless code via a data channel based on the scheduling information, where each of the set of packets includes an encoding symbol. The operations of 1315 may be performed according to the methods described herein. In some examples, aspects of the operations of 1315 may be performed by a packet communication component as described with reference to FIGS. 6 through 10.

At 1320, the UE or base station may decode the set of encoding symbols based on the set of encoding symbol identifiers. The operations of 1320 may be performed according to the methods described herein. In some examples, aspects of the operations of 1320 may be performed by a decoding component as described with reference to FIGS. 6 through 10.

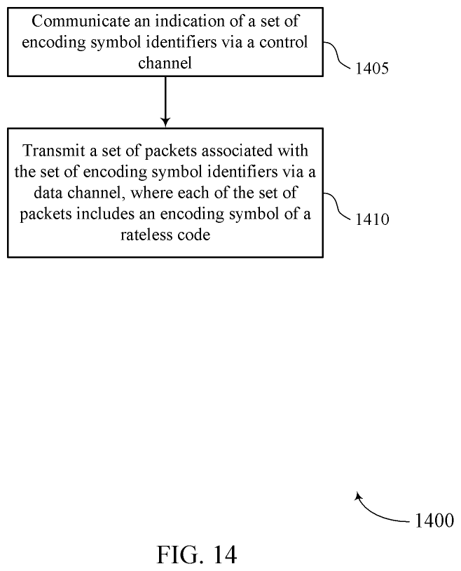

FIG. 14 shows a flowchart illustrating a method 1400 that supports information indication for raptor codes in accordance with aspects of the present disclosure. The operations of method 1400 may be implemented by a UE 115 or base station 105 or its components as described herein. For example, the operations of method 1400 may be performed by a communication manager as described with reference to FIGS. 6 through 10. In some examples, a UE or base station may execute a set of instructions to control the functional elements of the UE or base station to perform the described functions. Additionally or alternatively, a UE or base station may perform aspects of the described functions using special-purpose hardware.

At 1405, the UE or base station may communicate an indication of a set of encoding symbol identifiers via a control channel. The operations of 1405 may be performed according to the methods described herein. In some examples, aspects of the operations of 1405 may be performed by an ESI communication component as described with reference to FIGS. 6 through 10.

At 1410, the UE or base station may transmit a set of packets associated with the set of encoding symbol identifiers via a data channel, where each of the set of packets includes an encoding symbol of a rateless code. The operations of 1410 may be performed according to the methods described herein. In some examples, aspects of the operations of 1410 may be performed by a packet communication component as described with reference to FIGS. 6 through 10.

It should be noted that the methods described herein describe possible implementations, and that the operations and the steps may be rearranged or otherwise modified and that other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communications systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies not explicitly mentioned herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed with a general-purpose processor, a DSP, an ASIC, a CPU, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described herein may be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one place to another. A non-transitory storage medium may be any available medium that may be accessed by a general-purpose or special purpose computer. By way of example, and not limitation, non-transitory computer-readable media may include RAM, ROM, electrically erasable programmable ROM (EEPROM), flash memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

As used herein, including in the claims, “or” as used in a list of items (e.g., a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.”

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label, or other subsequent reference label.

The description set forth herein, in connection with the appended drawings, describes example configurations and does not represent all the examples that may be implemented or that are within the scope of the claims. The term “example” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

1. A method for wireless communication, comprising:
communicating an indication of a plurality of encoding symbol identifiers via a control channel;
receiving a plurality of packets associated with a rateless code via a data channel, wherein each of the plurality of packets comprises an encoding symbol; and
decoding the plurality of encoding symbols based at least in part on the plurality of encoding symbol identifiers.

2. The method of claim 1, wherein communicating the indication of the plurality of encoding symbol identifiers comprises:
communicating control signaling via the control channel and comprising the indication of the plurality of encoding symbol identifiers.

3. The method of claim 2, wherein the control signaling comprises a downlink control information message comprising the indication of the plurality of encoding symbol identifiers, a radio resource control message comprising the indication of the plurality of encoding symbol identifiers, or a medium access control (MAC) control element message comprising the indication of the plurality of encoding symbol identifiers.

4. The method of claim 1, wherein communicating the indication of the plurality of encoding symbol identifiers comprises communicating scheduling information via the control channel, and wherein the plurality of packets are received based at least in part on the scheduling information, the method further comprising:
generating the plurality of encoding symbol identifiers based at least in part on the scheduling information.

5. The method of claim 4, wherein the scheduling information comprises a position of one or more resource blocks, a system frame number, a slot number, or a symbol number, and wherein generating the plurality of encoding symbol identifiers is based at least in part on the position of the one or more resource blocks, the system frame number, the slot number, the symbol number, or a combination thereof.

6. The method of claim 1, further comprising:
communicating control signaling comprising an indication of a source block number.

7. The method of claim 6, wherein decoding the plurality of encoding symbols based at least in part on communicating the indication of the source block number.

8. The method of claim 6, wherein the control signaling comprises a downlink control information message comprising the indication of the source block number, a radio resource control message comprising the indication of the source block number, or a medium access control (MAC) control element message comprising the indication of the source block number.

9. The method of claim 6, wherein each packet of the plurality of packets excludes any indication of the source block number based at least in part on communicating the indication of the source block number.

10. The method of claim 6, wherein communicating the control signaling comprising the indication of the source block number comprises:
receiving, at a user equipment, the indication of the source block number.

11. The method of claim 6, wherein communicating the control signaling comprising the indication of the source block number comprises:
transmitting, from a base station, the indication of the source block number.

12. The method of claim 1, wherein receiving the plurality of packets comprises receiving a first transport block, wherein the first transport block comprises a plurality of first code blocks comprising the plurality of packets, and wherein the plurality of packets comprises a plurality of first packets associated with a first redundancy version, the method further comprising:
receiving a second transport block, wherein the second transport block comprises a plurality of second code blocks comprising a plurality of second packets associated with a second redundancy version; and
transmitting an indication of a number of one or more of the plurality of second code blocks based at least in part on failing to successfully decode the one or more of the plurality of second code blocks, wherein the plurality of first packets are received based at least in part on transmitting the indication of the number.

13. The method of claim 12, wherein each of the plurality of second code blocks is associated with a respective one of the plurality of first code blocks, the method further comprising:
identifying a failure to decode a code block of the plurality of first code blocks that is unassociated with any of the plurality of second code blocks; and
performing a soft combination procedure using the plurality of first code blocks and the plurality of second code blocks based at least in part on identifying the failure and the plurality of encoding symbols, wherein decoding the plurality of first code blocks is based at least in part on performing the soft combination procedure.

14. The method of claim 12, wherein each of the plurality of second code blocks is associated with a respective one of the plurality of first code blocks, the method further comprising:
decoding a code block of the plurality of first code blocks that is unassociated with any of the plurality of second code blocks, wherein decoding the plurality of first packets is based at least in part on decoding the code block unassociated with any code blocks of the plurality of second code blocks.

15. The method of claim 1, further comprising:
transmitting an acknowledgement message based at least in part on decoding the plurality of encoding symbols.

16. The method of claim 1, wherein each packet of the plurality of packets excludes any indication of the plurality of encoding symbol identifiers based at least in part on communicating the indication of the plurality of encoding symbol identifiers.

17. The method of claim 1, wherein:
decoding the plurality of encoding symbols comprises performing the decoding according to a raptor code on the plurality of encoding symbols to generate a plurality of source symbols.

18. The method of claim 1, wherein communicating the indication of the plurality of encoding symbol identifiers comprises:
receiving, at a user equipment, the indication of the plurality of encoding symbol identifiers.

19. The method of claim 1, wherein communicating the indication of the plurality of encoding symbol identifiers comprises:
transmitting, from a base station, the indication of the plurality of encoding symbol identifiers.

20. A method for wireless communication, comprising:
communicating an indication of a plurality of encoding symbol identifiers via a control channel; and
transmitting a plurality of packets associated with the plurality of encoding symbol identifiers via a data channel, wherein each of the plurality of packets comprises an encoding symbol of a rateless code.

21. The method of claim 20, wherein communicating the indication of the plurality of encoding symbol identifiers comprises:
communicating control signaling via the control channel and comprising the indication of the plurality of encoding symbol identifiers.

22. The method of claim 21, wherein the control signaling comprises a downlink control information message comprising the indication of the plurality of encoding symbol identifiers, a radio resource control message comprising the indication of the plurality of encoding symbol identifiers, or a medium access control (MAC) control element message comprising the indication of the plurality of encoding symbol identifiers.

23. The method of claim 20, wherein communicating the indication of the plurality of encoding symbol identifiers comprises communicating scheduling information via the control channel, the method further comprising:
generating the plurality of encoding symbol identifiers based at least in part on the scheduling information, wherein communicating the plurality of packets is based at least in part on the plurality of encoding symbol identifiers.

24. The method of claim 23, wherein the scheduling information comprises a position of one or more resource blocks, a system frame number, a slot number, or a symbol number, and wherein generating the plurality of encoding symbol identifiers is based at least in part on the position of the one or more resource blocks, the system frame number, the slot number, the symbol number, or a combination thereof.

25. The method of claim 20, further comprising:
communicating control signaling comprising an indication of a source block number.

26. The method of claim 25, wherein the control signaling comprises a downlink control information message comprising the indication of the source block number, a radio resource control message comprising the indication of the source block number, or a medium access control (MAC) control element message comprising the indication of the source block number.

27. The method of claim 25, wherein each packet of the plurality of packets excludes any indication of the source block number based at least in part on receiving the indication of the source block number.

28. The method of claim 25, wherein communicating the control signaling comprising the indication of the source block number comprises:
receiving, at a user equipment, the indication of the source block number.

29. The method of claim 25, wherein communicating the control signaling comprising the indication of the source block number comprises:
transmitting, from a base station, the indication of the source block number.

30. The method of claim 20, wherein transmitting the plurality of packets comprises transmitting a first transport block, wherein the first transport block comprises a plurality of first code blocks comprising the plurality of packets, and wherein the plurality of packets comprises a plurality of first packets associated with a first redundancy version, the method further comprising:
transmitting a second transport block, wherein the second transport block comprises a plurality of second code blocks comprising a plurality of second packets associated with a second redundancy version; and
receiving an indication of a number of one or more of the plurality of second code blocks, wherein the indication of the number indicates a failure to successfully decode the one or more of the plurality of second code blocks, wherein the plurality of first packets are transmitted based at least in part on receiving the indication of the number.

31. The method of claim 20, further comprising:
receiving an acknowledgement message based at least in part on transmitting the plurality of packets.

32. The method of claim 20, wherein each packet of the plurality of packets excludes any indication of the plurality of encoding symbol identifiers based at least in part on communicating the indication of the plurality of encoding symbol identifiers.

33. The method of claim 20, further comprising:
encoding a plurality of source symbols using a raptor code to generate the plurality of encoding symbols.

34. The method of claim 20, wherein communicating the indication of the plurality of encoding symbol identifiers comprises:
receiving, at a user equipment, the indication of the plurality of encoding symbol identifiers.

35. The method of claim 20, wherein communicating the indication of the plurality of encoding symbol identifiers comprises:
transmitting, from a base station, the indication of the plurality of encoding symbol identifiers.

36-140. (canceled)
